(19) United States
(12) Patent Application Publication
(10) Pub. No.: US 2011/0241178 A1
(43) Pub. Date: Oct. 6, 2011

(54) SEMICONDUCTOR DEVICE AND METHOD OF MANUFACTURING THE SAME

(75) Inventor: Keiji Miki, Kyoto (JP)

(73) Assignee: PANASONIC CORPORATION, Osaka (JP)

(21) Appl. No.: 13/077,322

(22) Filed: Mar. 31, 2011

(30) Foreign Application Priority Data
Apr. 1, 2010 (JP) 2010-084728

(51) Int. Cl. H01L 21/78; H01L 23/28

(52) U.S. Cl. 257/620; 438/462; 257/E23.116; 257/E21.599

(57) ABSTRACT

An organic protective film 23′ is formed on the periphery of a chip region 12 on a substrate 11 so as to continuously surround the internal part of the chip region 12. A passivation film 22 and an organic protective film 23 form a closed-loop opening on a cap layer 47.

### FIELD OF THE INVENTION

The present invention relates to semiconductor devices and a method of manufacturing the same in which a plurality of semiconductor chips are formed on a semiconductor wafer and a scribe region is diced to obtain the semiconductor devices.

### BACKGROUND OF THE INVENTION

Generally, semiconductor devices are formed by arranging a large number of integrated circuits (ICs) in a matrix on a semiconductor wafer, e.g., a silicon wafer, the IC including multiple elements with predetermined functions.

Further, multiple chip regions on a wafer are separated by a scribe region (scribe lines) arranged in a grid-like fashion. After Multiple chip regions are formed on a single wafer through a semiconductor manufacturing process, the wafer is ground from the back side to a predetermined thickness and is diced into individual chips along the scribe region, and then the chips are mounted, so that individual semiconductor devices are obtained.

When a wafer is diced into individual chips, unfortunately, an interlayer insulating film having high permeability and hygroscopicity is exposed on the end faces of the chip. Thus moisture and mobile ions which have permeated into the interlayer insulting film from the end faces of the chip may come into the chip and corrode wires, leading to degradation in the resistance of the insulating film and the properties of elements. Further, when the wafer is divided into individual chips by dicing, a mechanical shock to chip regions around scribe lines may cause cracks or chipping on the dicing faces of the separated chips.

In some cases, for protection against the entry of moisture and mobile ions and a mechanical shock in a semiconductor device of the related art, a ring barrier called a seal ring is provided around a chip region.

FIG. 24 is an enlarged view showing the principle part of the configuration of a semiconductor device including a seal ring according to the related art. FIG. 25 is a sectional view for explaining the configuration of the semiconductor device including the seal ring according to the related art. FIG. 25 shows a sectional structure taken along line A-A′ of FIG. 24. FIG. 26 is an explanatory drawing showing the configuration of a wafer on which the multiple semiconductor devices are formed according to the related art. FIG. 26 shows that the semiconductor devices having the seal rings are formed on a wafer substrate.

As shown in FIGS. 24 and 25, on a wafer substrate 111, a plurality of chip regions 112 are formed that are separated by a scribe region 113. Further, a laminated insulating film 170 including interlayer insulating films 115 to 120 is formed on the substrate 111.

In the chip region 112, an active layer 130 constituting an element is formed on the substrate 111. In the laminated insulating film 170, a wiring structure 171 connected to the active layer 130 is formed. To be specific, a via 131 connected to the active layer 130 is formed in the interlayer insulating film 115, a wire 132 connected to the via 131 is formed in the interlayer insulating film 116, a via 133 connected to the wire 132 is formed in the interlayer insulating film 117, a wire 134 connected to the via 133 is formed in the interlayer insulating film 118, a via 135 connected to the wire 134 is formed in the interlayer insulating film 119, and a wire 136 connected to the via 135 is formed in the interlayer insulating film 120. The wiring structure 171 is configured thus.

On the laminated structure of the interlayer insulating films 115 to 120 at the periphery of the chip region 112, a seal ring 114 is formed that penetrates the laminated structure and continuously surrounds the chip region 112. The seal ring 114 is formed by alternatively stacking seal wires formed with a wiring forming mask and seal vias formed with a via forming mask. Specifically, the seal ring 114 includes a conductive layer 140 formed on the substrate 111, a seal via 141 that is formed in the interlayer insulating film 115 and is connected to the conductive layer 140, a seal wire 142 that is formed in the interlayer insulating film 116 and is connected to the seal via 141, a seal via 143 that is formed in the interlayer insulating film 117 and is connected to the seal wire 142, a seal wire 144 that is formed in the interlayer insulating film 118 and is connected to the seal via 143, a seal via 145 that is formed in the interlayer insulating film 119 and is connected to the seal wire 144, and a seal wire 146 that is formed in the interlayer insulating film 120 and is connected to the seal via 145.

On the laminated insulating film 170 including the wires (132, 134, 136), vias (131, 133, 135), and the seal ring 114, a passivation film 121 is provided. The passivation film 121 is opened on the wire 136 and the seal wire 146. On the respective openings, a pad 137 connected to the wire 136 and a cap layer 147 connected to the seal wire 146 are formed.

On the passivation film 121, another passivation film 122 is formed that is opened above the seal ring 114 and on the pad 137. Further, a protective film 123 is formed to protect the chip region 112, the protective film 123 being opened on and around the pad 137 and on the seal ring 114.

In the configuration of FIGS. 24 and 25, a barrier is provided for blocking a mechanical shock during dicing, thereby preventing cracks from developing to the chip region 112. Since the passivation film 121 has an opening on the seal ring 114, the passivation film on the chip region 112 is not peeled off by a shock during dicing. Further, the cap layer 147 formed on the opening of the passivation film 121 on the seal ring 114 can prevent moisture and impurities from entering the chip region 112 from the scribe region during dicing, unlike in the absence of the cap layer 147.

It is known that the semiconductor device configured thus has disadvantages as follows:

Generally, in a semiconductor manufacturing process, the chip regions 112 configured as shown in FIGS. 24 and 25 are formed on the wafer substrate 111. After that, the wafer is ground from the back side to a predetermined thickness and then is diced into individual chips in the scribe region 113.

In the backside grinding, a protective sheet is bonded to a wafer surface, that is, a pattern formation surface and a high-speed grindstone is pressed to the back side of the wafer to grind the back side of the wafer. During grinding, water is sprayed to wash off generated abatement and dissipate frictional heat generated by grinding.

As shown in FIG. 26, the scribe region 113 is formed to the outermost periphery of the wafer. Further, the protective film 123 is formed on the chip region 112. The protective film 123 is provided to protect the chip region 112 from scratches and contamination and has a certain thickness (about 5 μm). Thus there is a height difference between the scribe region 113 and the protective film 123. Protective tape for backside grinding cannot eliminate the height difference and a gap may be formed between the protective tape and the scribe region 113.

During backside grinding, cutting fluid containing abatement may enter the gap on the outer periphery of the wafer and spread along a scribe line into the wafer, leading to contamination on chip surfaces.

Patent document 1 (Japanese Patent Laid-Open No. 2001-274129) discloses a technique in which when a protective film (polyimide film) for protecting a chip region is patterned, banks are formed near the intersections of scribe lines arrayed in a grid-like fashion, and then dicing is performed on the scribe lines. In this method, even if cutting fluid :containing abatement enters a wafer from a gap between the scribe lines and masking tape, the banks on the scribe lines prevent the cutting fluid from flawing over the banks, thereby preventing contamination of electrode pads and a chip surface in the chip region disposed next to the banks.

In dicing following the backside grinding, a disc-shaped dicing blade is pressed along the scribe region 113 to divide the wafer into individual chips. In many cases, monitor elements for confirming the characteristics of semiconductor elements or various process values in a semiconductor manufacturing process are formed in the scribe region 113 and the characteristics of the semiconductor elements are inspected through electrode pads connected to the monitor elements, so that the quality of a semiconductor chip is estimated and the presence or absence of an abnormality is determined in the semiconductor manufacturing process. Such monitor elements and electrode pads for characteristic inspections are called an accessory pattern and may increase the occurrence of chipping or peeling of the pattern during dicing, leading to lower yields.

Patent document 2 (Japanese Patent Laid-Open No. 2005-183866) discloses that a protective film (polyimide film) covers a part of an accessory pattern on a scribe region, so that the accessory pattern is pressed by the protective film and is less likely to be peeled off during dicing. Japanese Patent Laid-Open No. 2005-183866 further discloses that the protective film covering only a part of the accessory pattern does not affect a dicing blade unlike in the case where a protective film such as a polyimide film covers the scribe region. The protective film covering the scribe region may adhere to a dicing blade and cause clogging, reducing the life of the dicing blade.

In response to recent downsizing and greater packaging densities, in many cases, copper wires with relatively low resistance have been used as wiring materials and materials called low-k materials with low relative dielectric constants have been used for interlayer insulating films. Films made of low-k materials have, however, low mechanical strength and are. likely to be chipped or peeled off during dicing, leading to lower yields and lower quality.

To address this problem, patent document 3 (Japanese Patent Laid-Open No. 2006-140404) discloses a technique in which a recessed part formed outside a seal ring in plan view prevents peeling from reaching the seal ring. According to this method, even if chipping occurring on a silicon substrate in dicing develops toward a circuit forming region, a stress concentrates on the recessed part and thus lateral development of peeling is suppressed.

In recent years, semiconductor devices have been reduced in size for use in portable equipment and thinner chips have been increasingly demanded, accordingly. For example, many chips are 100 μm or less in thickness.

However, in the manufacturing method of the related art, to be specific, in a manufacturing method of forming multiple chip regions on a wafer before backside grinding and dicing, the wafer may be warped after backside grinding or the wafer may be cracked in a transfer process of a system. Further, the ground wafer may be cracked by wrong handling. In dicing of a wafer ground to a thickness less than 100 μm, an impact upon dicing may crack chips. Such cracks reduce manufacturing yields and product quality.

To address this problem, patent document 4 (Japanese Patent Laid-Open No. 5-335411) discloses a technique in which grooves are formed beforehand along scribe, lines on the front side of a wafer, and then the back side of the wafer is ground to allow the formed grooves to communicate with the back side of the wafer in the backside grinding, so that the wafer is divided into individual chips. According to this method, processing on a wafer having a sufficiently large thickness hardly causes cracks and the grooves are formed by partially making cuts from the front side of the wafer in the thickness direction, thereby suppressing the occurrence of cracks.

This method is called a dicing before grinding (DBG) process, which is particularly effective in the case where a wafer has a large diameter and backside grinding is performed to a small thickness.

### DISCLOSURE OF THE INVENTION

Unfortunately, the foregoing techniques have the following problems:

In the technique of patent document 1, the entry of cutting fluid can be suppressed by the banks provided on the scribe lines. In the subsequent dicing, however, the protective film on the scribe lines may cause clogging on the dicing blade. Thus chipping may increase and result in lower quality and yields.

In the technique of patent document 4 in response to the needs for thinner chips, a protective film formed at the intersections of the scribe lines (near the corners of chip regions) cannot act as banks. In other words, since the grooves have been already formed on the scribe lines upon backside grinding, cutting fluid may pass through the grooves and contaminate the chip regions.

In the technique of patent document 2, the protective film covering a part of the accessory pattern on a surface layer can suppress peeling of the accessory pattern to some extent, but as has been discussed, in the case where a low-dielectric constant film made of an interlayer insulating material, e.g., a low-k material is used in response to downsizing and greater packaging densities, the interlayer insulating film is likely to be peeled off and thus the suppressive effect is not enough.

In the technique of patent document 3, the recessed part is formed beforehand outside the seal ring to suppress peeling of the low-dielectric constant film, so that a stress is concentrated on the recessed part and peeling is prevented from reaching the seal ring. Also in this case, a recess depth leading to high productivity and the effect of suppressing peeling have a trade-off relationship. Thus in the case where primary importance is attached to safety for vehicle use, this configuration is not sufficiently effective for protection of chip regions. Further, if chipping or peeling cannot be suppressed on the recessed part and reaches the seal ring, peeling may develop into a chip and result in low reliability because a surface protective film (passivation film) is connected into a chip region on the seal ring.

Solutions to these problems have been demanded.

In order to solve these problems, an object of a semiconductor device and a method of manufacturing the same according to the present invention is to suppress physical damages such as moisture contamination, breaking, cracking, chipping, and interlayer peeling during backside grinding and dicing on a wafer.

In order to attain the object, a semiconductor device of the present invention includes: a semiconductor substrate; an electrode pad formed on the semiconductor substrate; a seal ring formed between the electrode pad and the outer periphery of the semiconductor substrate; a cap layer formed on the seal ring, the cap layer being connected to the seal ring a passivation film formed on the semiconductor substrate so as to expose the electrode pad and the cap layer; a first protective film formed on the passivation film and inside the seal ring so as to expose the electrode pad and the cap layer; and a second protective film formed on the passivation film and outside the seal ring so as to expose the cap layer.

Preferably, the semiconductor device further includes a first groove formed between the cap layer of the passivation film and the outer periphery of the semiconductor substrate, the first groove being shaped like a closed loop, in parallel with the outer periphery of the semiconductor substrate, wherein the second protective film is formed also in the first groove.

Preferably, the semiconductor device further includes a plurality of openings formed between the cap layer of the passivation film and the outer periphery of the semiconductor substrate, the openings being formed at intervals in parallel with the outer periphery of the semiconductor substrate, wherein the second protective film is formed also in the openings.

Preferably, the seal ring is octagonal in plan view and has a side at each corner of the semiconductor substrate.

Preferably, the semiconductor device further includes: a first groove formed between the cap layer of the passivation film and the outer periphery of the semiconductor substrate, the first groove being shaped like a closed loop in parallel with the outer periphery of the semiconductor substrate; and a second groove that is parallel to the seal ring at each corner of a chip region and is connected to the first groove at each end, wherein the second protective film is formed also in the first groove and the second groove and covers a triangle formed by the first groove and the second groove.

Preferably, the semiconductor device further includes: a plurality of first openings formed between the cap layer of the passivation film and the outer periphery of the semiconductor substrate, the first openings being formed at intervals in parallel with the outer periphery of the semiconductor substrate; and a plurality of second openings that are parallel to the seal ring at each corner of a chip region, are combined to be connected to the first openings at each end, and are formed at intervals, wherein the second protective film is formed also in the first openings and the second openings and covers a triangle formed by the first openings and the second openings.

A method of manufacturing the semiconductor device according to the present invention is a method of manufacturing a semiconductor device in which multiple chip regions formed on a wafer are separated by a scribe region, in formation of the chip region, the manufacturing method including the steps of: forming an element on a semiconductor substrate; forming a conductive layer on the periphery of the chip region; forming interlayer insulating films on the semiconductor substrate, forming a wiring structure in the interlayer insulating films, the wiring structure including wiring layers and vias such that the wiring layers and the vias are electrically connected to the element, simultaneously forming a seal ring in the interlayer insulating films and in the outer region of the chip region, the seal ring including seal wires and seal vias and continuously surrounding the wiring structure and the element, the seal wires and seal vias being electrically connected to the conductive layer; forming a first passivation film on the interlayer insulating films, the first passivation film having an electrode pad opening above the wiring structure and a cap layer opening above the seal ring; forming an electrode pad on the electrode pad opening, the electrode pad being connected to the wiring structure; forming a cap layer on the cap layer opening; forming a second passivation film on the first passivation film so as to expose the electrode pad and the cap layer; forming a first protective film on the second passivation film in the chip region and inside the seal ring so as to expose the electrode pad and the cap layer; and forming a second protective film on the second passivation film in the chip region and outside the seal ring so as to expose the cap layer.

Preferably, a first groove like a closed loop is further formed between the seal ring and the scribe region and in parallel with the outer periphery of the chip region in the step of forming the first passivation film, a second groove like a closed loop is further formed on the first groove and in parallel with the outer periphery of the chip region in the step of forming the second passivation film, and the second protective film is formed also in the first groove and the second groove in the step of forming the second protective film.

Preferably, a plurality of first openings are further formed between the seal ring and the scribe region, the first openings being formed at intervals in parallel with the outer periphery of the chip region, in the step of forming the first passivation film, a plurality of second openings are further formed on the respective first openings and in parallel with the outer periphery of the chip region in the step of forming the second passivation film, and the second protective film is formed also in the first openings and the second openings in the step of forming the second protective film.

Preferably, the manufacturing method further includes the steps of: bonding a protective sheet on the major surface of the semiconductor substrate having the protective film after the step of forming the second protective film, and grinding the semiconductor substrate to a predetermined thickness from the back side of the semiconductor substrate with respect to the major surface; and dividing the semiconductor substrate into the individual semiconductor devices by dicing the scribe region after the grinding step.

Preferably, the manufacturing method further includes the steps of: forming a third groove from the major surface having the second protective film after the step of forming the second protective film, the third groove having a predetermined depth in the scribe region of the semiconductor substrate; and bonding a protective sheet on the major surface of the semiconductor substrate after the step of forming the third groove, and dividing the semiconductor substrate into the individual semiconductor devices by grinding the semiconductor substrate to the third groove from the back side of the semiconductor substrate with respect to the major surface.

### BRIEF DESCRIPTION OF THE DRAWINGS

FIG. 1 is a plan view illustrating the principle part of the configuration of a semiconductor device according to a first embodiment;

FIG. 2A is a sectional view illustrating the principle part of the configuration of the semiconductor device according to the first embodiment;

FIG. 2B is a sectional view illustrating the principle part of the configuration of the semiconductor device according to the first embodiment;

FIG. 3A is a process sectional view showing a method of manufacturing the semiconductor device according to the first embodiment;

FIG. 3B is a process sectional view showing the method of manufacturing the semiconductor device according to the first embodiment;

FIG. 3C is a process sectional view showing the method of manufacturing the semiconductor device according to the first embodiment;

FIG. 3D is a process sectional view showing the method of manufacturing the semiconductor device according to the first embodiment;

FIG. 3E is a process sectional view showing the method of manufacturing the semiconductor device according to the first embodiment;

FIG. 4A is a process sectional view showing the method of manufacturing the semiconductor device according to the first embodiment;

FIG. 4B is a process sectional view showing the method of manufacturing the semiconductor device according to the first embodiment;

FIG. 4C is a process sectional view showing the method of manufacturing the semiconductor device according to the first embodiment;

FIG. 4D is a process sectional view showing the method of manufacturing the semiconductor device according to the first embodiment;

FIG. 5A is a process sectional view showing the method of manufacturing the semiconductor device according to the first embodiment;

FIG. 5B is a process sectional view showing the method of manufacturing the semiconductor device according to the first embodiment;

FIG. 5C is a process sectional view showing the method of manufacturing the semiconductor device according to the first embodiment;

FIG. 5D is a process sectional view showing the method of manufacturing the semiconductor device according to the first embodiment;

FIG. 6A is a process sectional view showing the method of manufacturing the semiconductor device according to the first embodiment;

FIG. 6B is a process sectional view showing the method of manufacturing the semiconductor device according to the first embodiment;

FIG. 7A is a process sectional view showing the method of manufacturing the semiconductor device according to the first embodiment;

FIG. 7B is a process sectional view showing the method of manufacturing the semiconductor device according to the first embodiment;

FIG. 8A is a process sectional view showing the method of manufacturing the semiconductor device according to the first embodiment;

FIG. 8B is a process sectional view showing the method of manufacturing the semiconductor device according to the first embodiment;

FIG. 8C is a process sectional view showing the method of manufacturing the semiconductor device according to the first embodiment;

FIG. 9 is a plan view illustrating the principle part of the configuration of a semiconductor device according to a second embodiment;

FIG. 10A is a sectional view illustrating the principle part of the configuration of the semiconductor device according to the second embodiment;

FIG. 10B is a sectional view illustrating the principle part of the configuration of the semiconductor device according to the second embodiment;

FIG. 11A is a process sectional view showing a method of manufacturing the semiconductor device according to the second embodiment;

FIG. 11B is a process sectional view showing the method of manufacturing the semiconductor device according to the second embodiment;

FIG. 12 is a plan view illustrating the principle part of the configuration of a semiconductor device according to a third embodiment;

FIG. 13A is a sectional view illustrating the principle part of the configuration of the semiconductor device according to the third embodiment;

FIG. 13B is a sectional view illustrating the principle part of the configuration of the semiconductor device according to the third embodiment;

FIG. 14A is a process sectional view showing a method of manufacturing the semiconductor device according to the third embodiment;

FIG. 14B is a process sectional view showing the method of manufacturing the semiconductor device according to the third embodiment;

FIG. 14C is a process sectional view showing the method of manufacturing the semiconductor device according to the third embodiment;

FIG. 14D is a process sectional view showing the method of manufacturing the semiconductor device according to the third embodiment;

FIG. 15 is a plan view illustrating the principle part of the configuration of a semiconductor device according to a fourth embodiment;

FIG. 16A is a sectional view illustrating the principle part of the configuration of the semiconductor device according to the fourth embodiment;

FIG. 16B is a sectional view illustrating the principle part of the configuration of the semiconductor device according to the fourth embodiment;

FIG. 17A is a process sectional view showing a method of manufacturing the semiconductor device according to the fourth embodiment;

FIG. 17B is a process sectional view showing the method of manufacturing the semiconductor device according to the fourth embodiment;

FIG. 17C is a process sectional view showing the method of manufacturing the semiconductor device according to the fourth embodiment;

FIG. 17D is a process sectional view showing the method of manufacturing the semiconductor device according to the fourth embodiment;

FIG. 18A is a process sectional view showing the method of manufacturing the semiconductor device according to the fourth embodiment;

FIG. 18B is a process sectional view showing the method of manufacturing the semiconductor device according to the fourth embodiment;

FIG. 18C is a process sectional view showing the method of manufacturing the semiconductor device according to the fourth embodiment;

FIG. 18D is a process sectional view showing the method of manufacturing the semiconductor device according to the fourth embodiment;

FIG. 19A is a process sectional view showing the method of manufacturing the semiconductor device according to the fourth embodiment;

FIG. 19B is a process sectional view showing the method of manufacturing the semiconductor device according to the fourth embodiment;

FIG. 19C is a process sectional view showing the method of manufacturing the semiconductor device according to the fourth embodiment;

FIG. 20 is a plan view illustrating the principle part of the configuration of a semiconductor device according to a fifth embodiment;

FIG. 21A is a sectional view illustrating the principle part of the configuration of the semiconductor device according to the fifth embodiment;

FIG. 21B is a sectional view illustrating the principle part of the configuration of the semiconductor device according to the fifth embodiment;

FIG. 22A is a process sectional view showing a method of manufacturing the semiconductor device according to the fifth embodiment;

FIG. 22B is a process sectional view showing the method of manufacturing the semiconductor device according to the fifth embodiment;

FIG. 22C is a process sectional view showing the method of manufacturing the semiconductor device according to the fifth embodiment;

FIG. 22D is a process sectional view showing the method of manufacturing the semiconductor device according to the fifth embodiment;

FIG. 23A is a process sectional view showing the method of manufacturing the semiconductor device according to the fifth embodiment;

FIG. 23B is a process sectional view showing the method of manufacturing the semiconductor device according to the fifth embodiment;

FIG. 23C is a process sectional view showing the method of manufacturing the semiconductor device according to the fifth embodiment;

FIG. 23D is a process sectional view showing the method of manufacturing the semiconductor device according to the fifth embodiment;

FIG. 24 is an enlarged view showing the principle part of the configuration of a semiconductor device including a seal ring according to the related art;

FIG. 25 is a sectional view for explaining the configuration of the semiconductor device including the seal ring according to the related art; and

FIG. 26 is an explanatory drawing showing the configuration of a wafer on which the multiple semiconductor devices are formed according to the related art.

### DESCRIPTION OF THE EMBODIMENTS

The following will describe embodiments of the present invention with reference to the accompanying drawings. The common configurations of the different embodiments will be indicated by the same reference numerals and the detailed explanation thereof may be omitted.

### First Embodiment

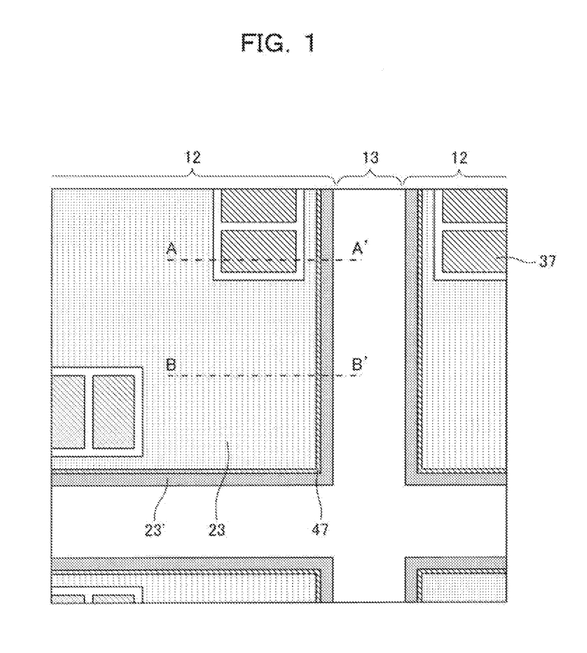

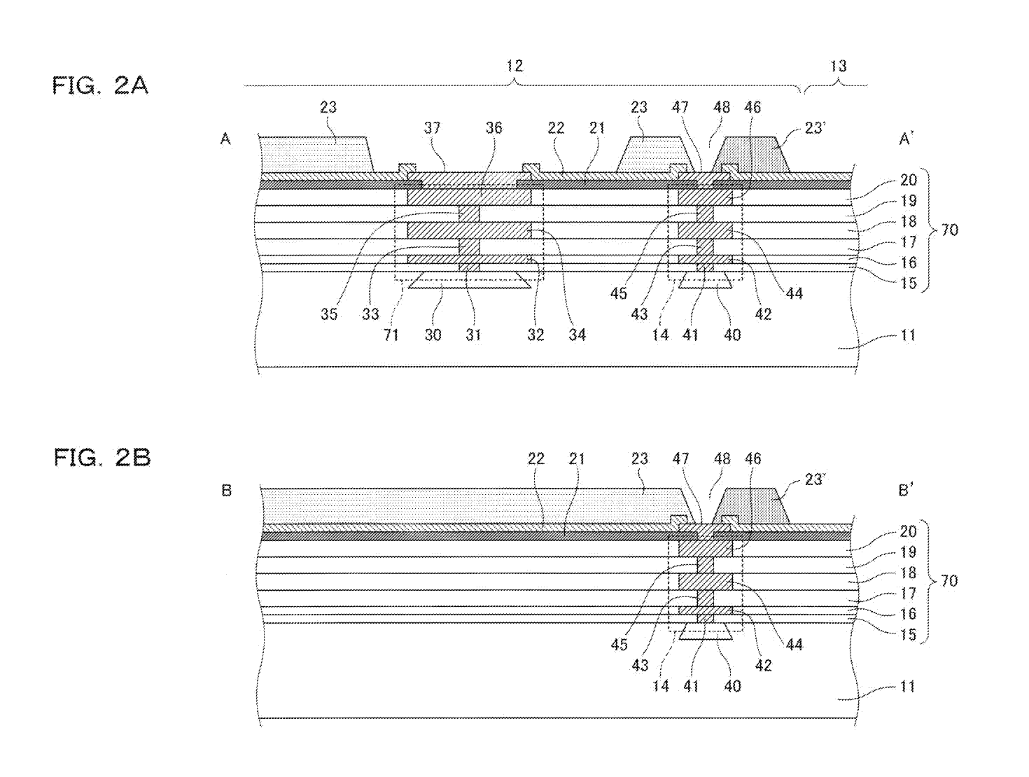

Referring to FIGS. 1 to 8C, a first embodiment will be described below. FIG. 1 is a plan view illustrating the principle part of the configuration of a semiconductor device according to the first embodiment. FIGS. 2A and 2B are sectional views illustrating the principle part of the configuration of the semiconductor device according to the first embodiment. FIGS. 2A and 2B show sectional structures taken along lines A-A′ and B-B′ of FIG. 1, respectively. In the drawings, a plurality of chip regions 12 and a scribe region 13 for separating the chip regions 12 by dicing are formed on a wafer.

The semiconductor device is formed from a substrate 11. On the substrate 11, a laminated insulating film 70 is formed in which interlayer insulating films 15, 16, 17, 18, 19, and 20 are stacked in this order.

In the chip region 12, an active layer 30 constituting an element (the element is not shown) is formed on the top of the substrate 11, and a wiring structure 71 connected to the active layer 30 is formed in the laminated insulating film 70. The wiring structure 71 includes a via 31 that is formed in the interlayer insulating film 15 and is connected to the active layer 30, a wire 32 that is formed in the interlayer insulating film 16 and is connected to the via 31, a via 33 that is formed in the interlayer insulating film 17 and is connected to the wire 32, a wire 34 that is formed in the interlayer insulating film 18 and is connected to the via 33, a via 35 that is formed in the interlayer insulating film 19 and is connected to the wire 34, and a wire 36 that is formed in the interlayer insulating film 20 and is connected to the via 35.

On the periphery of the chip region 12, a conductive layer 40 is formed on the top of the substrate 11 and a seal ring 14 penetrating the laminated insulating film 70 is formed. The conductive layer 40 and the seal ring 14 are formed along the periphery of the chip region 12 so as to continuously surround the active layer 30, the wiring structure 71, and so on. The seal ring 14 is formed by alternatively stacking seal wires formed with a wiring forming mask and seal vias formed with a via forming mask. To be specific, the seal ring 14 includes: a seal via 41 that is formed in the interlayer insulating film 15 and is connected to the conductive layer 40; a seal wire 42 that is formed in the interlayer insulating film 16 and is connected to the seal via 41; a seal via 43 that is formed in the interlayer insulating film 17 and is connected to the seal wire 42; a seal wire 44 that is formed in the interlayer insulating film 18 and is connected to the seal via 43; a seal via 45 that is formed in the interlayer insulating film 19 and is connected to the seal wire 44; and a seal wire 46 that is formed in the interlayer insulating film 20 and is connected to the seal via 45.

Further, a passivation film 21 is formed so as to cover the laminated insulating film 70 including the wiring structure 71 and the seal ring 14. The passivation film 21 has openings on the wiring structure 71 (wire 36) and the seal ring 14 (seal wire 46), respectively. On the respective openings, a pad electrode 37 connected to the wire 36 and a cap layer 47 connected to the seal wire 46 are formed.

On the passivation film 21, a passivation film 22 is formed except for the top of the pad electrode 37 and the top of the cap layer 47. On the passivation film 22, an organic protective film 23 having an opening on and near the pad electrode 37 and an opening on the seal ring 14 is formed to protect the chip region 12. Between the seal ring 14 in the chip region 12 and the scribe region 13, a protective film 23′ shaped like a closed loop is formed so as to surround the internal part of the chip region 12.

In other words, the organic protective film includes the protective film 23 for protecting an element forming region and the protective film 23′ that is shaped like a closed loop between the seal ring 14 and the scribe region 13 so as to surround the internal part of the chip region 12. The passivation film 22 and the organic protective films 23 and 23′ are formed such that the protective film 23 formed in the chip region 12 and the protective film 23′ formed next to the scribe region 13 are separated by a opening 48 that is shaped like a closed loop so as to partially expose the cap layer 47.

As shown in FIGS. 1, 2A, and 2B, the protective film 23 is formed outside the pad electrode Of the chip region 12 and the protective film 23′ separated from the protective film 23 by the opening 48 is formed over the outer periphery of the chip region 12 along the scribe region 13. Thus during backside grinding, it is possible to avoid contamination caused by cutting fluid on the surface of the chip region 12. Specifically, when protective tape is bonded in backside grinding, a sticking roller presses the ring part of the organic protective film 23′ formed next to the scribe region 13, rather than the closed-loop opening of the passivation film 22, so that the organic protective film 23′ surrounding the internal part of the chip region 12 and the protective tape can be brought into contact with each other. With this configuration, even if cutting fluid for backside grinding enters from a gap between the protective tape and the scribe region 13, the entry of the cutting fluid into the chip region 12 is suppressed. Consequently, contamination on the chip region 12 is reduced.

Even if chipping or peeling occurs during dicing, the development of peeling or damage to the element forming region inside the seal ring 14 can be prevented by the closed-loop opening on the passivation film 22 and the continuously formed opening 48 between the organic protective films 23 and 23′ and above the seal ring.

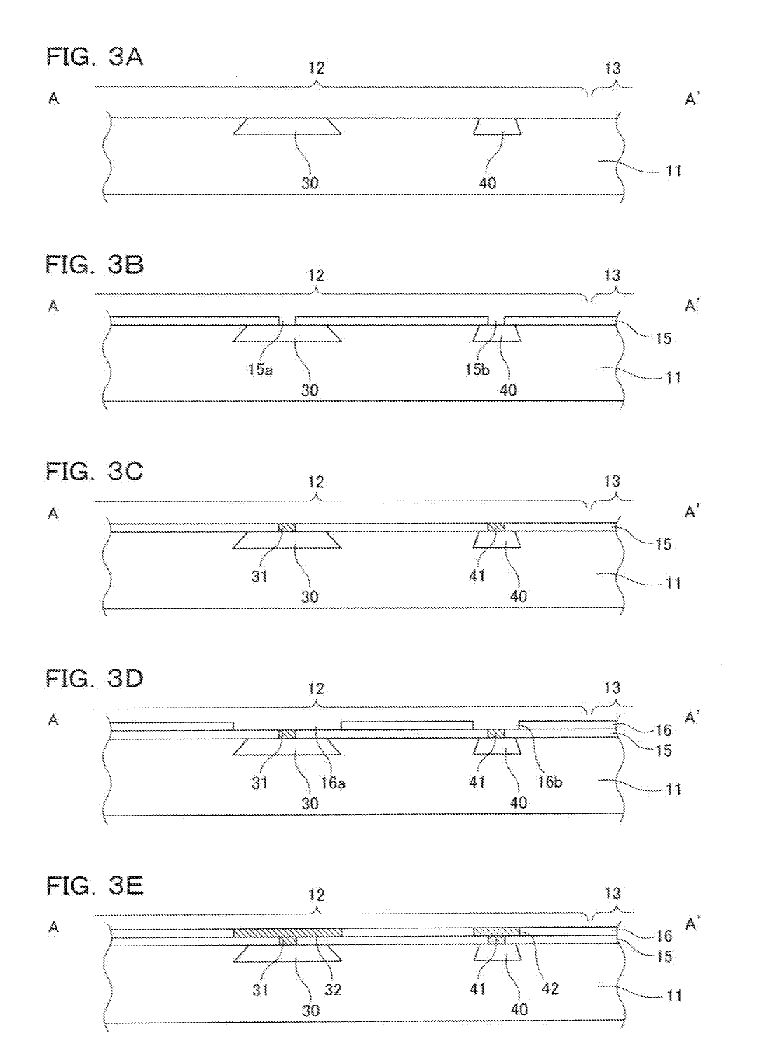

Referring to FIGS. 3A to 8C, the following will describe a manufacturing method for forming the structure shown in FIGS. 1, 2A, and 2B and a method of separating the chip regions 12 as individual semiconductor devices by dicing.

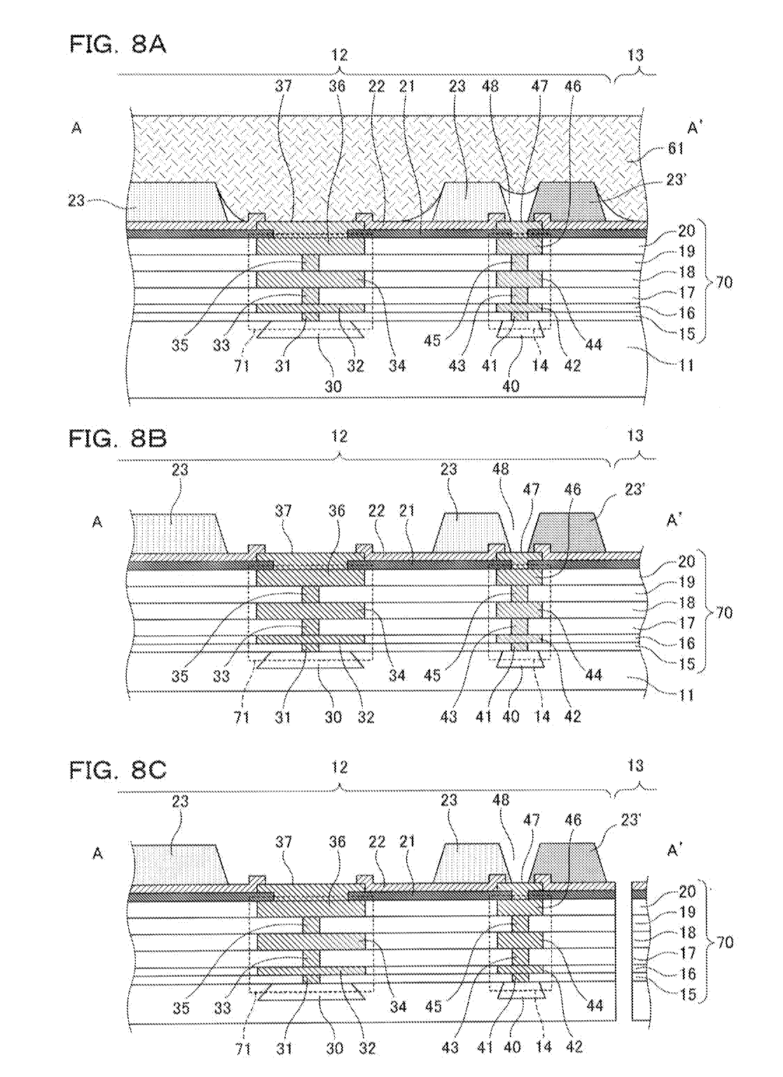

FIGS. 3A to 3E, 4A to 4D, 5A to 5D, 6A, 6B, 7A, 7B, and 8A to 8C are process sectional views showing the method of manufacturing the semiconductor device according to the first embodiment. The steps of forming the structure are illustrated in cross section taken along line A-A′ of FIG. 1. FIGS. 8A to 8C are explanatory drawings showing, in particular, backside grinding and dicing.

First, as shown in FIG. 3A, the active layer 30 constituting a device such as a transistor is formed in the chip region 12 of the wafer (substrate 11) and the surrounding conductive layer 40 is formed outside the active layer 30 such that the conductive layer 40 is continuously formed over the periphery of the chip region 12 and around the internal part of the chip region 12.

Next, as shown in FIG. 3B, the interlayer insulating film 15 is deposited on the substrate 11. Further, a via hole 15a for forming the via 31 in the interlayer insulating film 15 is formed on the active layer 30, and a groove portion 15b for forming the seal via 41 is formed on the conductive layer 40. The via hole 15a and the groove portion 15b may be formed by lithography and dry etching.

In this configuration, the seal via 41 constitutes the seal ring 14 and is formed by applying a conductive material into the groove portion 15b. In other words, the seal via 41 has a linear structure having the same width as the via. Since the seal ring 14 continuously surrounds the element of the chip region 12, the seal via 41 also continuously surrounds the element.

In this example, the groove portion 15b is formed when the via hole 15a is formed on the interlayer insulating film 15. The present invention is not limited to the order of formation and the via hole 15a and the groove portion 15b may be formed at different times.

Next, the step of FIG. 3C is performed. First, a conductive film made of tungsten is applied into the via hole 15a and the groove portion 15b on the interlayer insulating film 15 by, e.g., chemical vapor deposition (CVD). Next, the protrusions of the conductive film out of the via hole 15a. and the groove portion 15b are removed by, e.g., chemical mechanical polishing (CMP). Thus the via 31 connected to the active layer 30 and the seal via 41 connected to the conductive layer 40 are formed.

Next, the step of FIG. 3D is performed. First, the interlayer insulating film 16 is deposited on the interlayer insulating film 15. Further, in the interlayer insulating film 16, a wire groove 16a for forming the wire 32 is formed on the via 31 and a seal wire groove 16b for forming the seal wire 42 is formed on the seal via 41. The wire groove 16a and the seal wire groove 16b may be formed by lithography and dry etching.

Next, the step of FIG. 3E is performed. First, a conductive film made of copper is applied into the wire groove 16a and the seal wire groove 16b on the interlayer insulating film 16 by, e.g., electroplating. Subsequently, the protrusions of the conductive film out of the wire groove 16a and the seal wire groove 16b are removed by, e.g., CMP, so that the wire 32 connected to the via 31 and the seal wire 42 connected to the seal via 41 are formed.

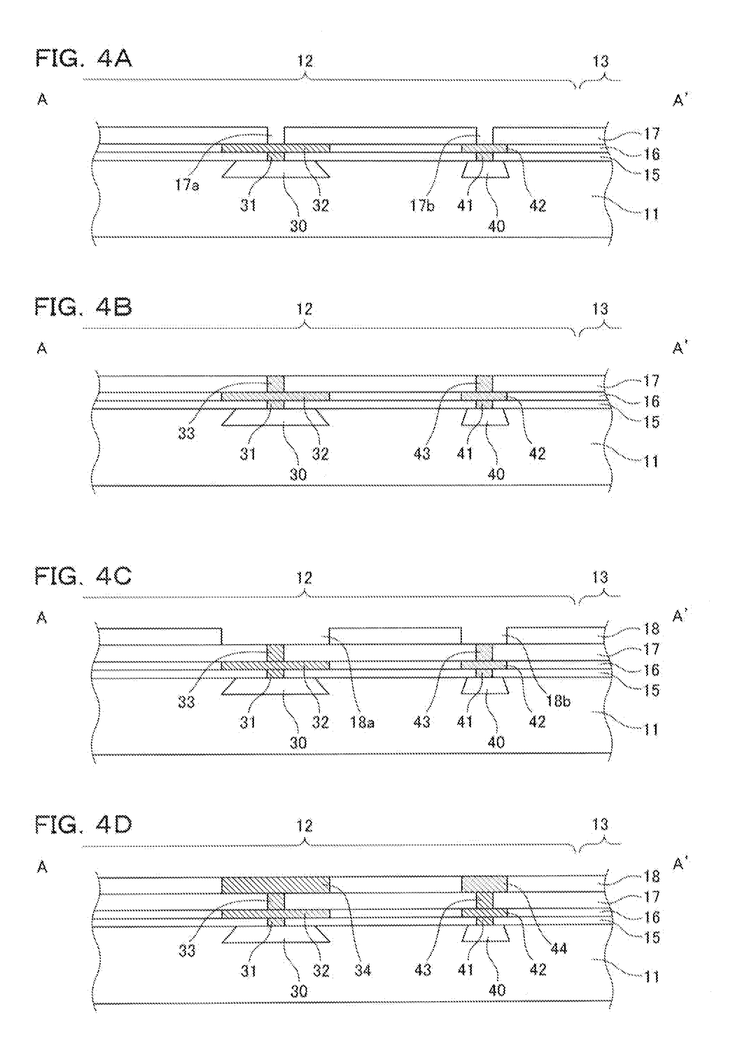

Next, the step of FIG. 4A is performed. First, the interlayer insulating film 17 is formed on the interlayer insulating film 16. Subsequently, in the interlayer insulating film 17, a via hole 17a for forming the via 33 is formed on the wire 32 and a groove portion 17b for forming the seal via 43 is formed on the seal wire 42. The via hole 17a and the groove portion 17b may be formed by the same method and materials as in the step of FIG. 3B.

Next, the step of FIG. 4B is performed. Specifically, the via hole 17a is filled to form the via 33 connected to the wire 32 and the groove portion 17b is filled to form the seal via 43 connected to the seal wire 42. The via 33 and the seal via 43 may be formed by the same method and materials as in the step of FIG. 3C.

Next, the step of FIG. 4C is performed. First, the interlayer insulating film 18 is forted on the interlayer insulating film 17. Subsequently, in the interlayer insulating film 18, a wire groove 18a for forming the wire 34 is formed on the via 33 and a seal wire groove 18b for forming the seal wire 44 is formed on the seal via 43. The wire groove 18a and the seal wire groove 18b may be formed by the same method and materials as in the step of FIG. 3D.

Next, the step of FIG. 4D is performed. Specifically, the wire groove 18a is filled to form the wire 34 connected to the via 33 and the seal wire groove 18b is filled to form the seal wire 44 connected to the seal via 43. The wire 34 and the seal wire 44 may be formed by the same method and materials as in the step of FIG. 3E.

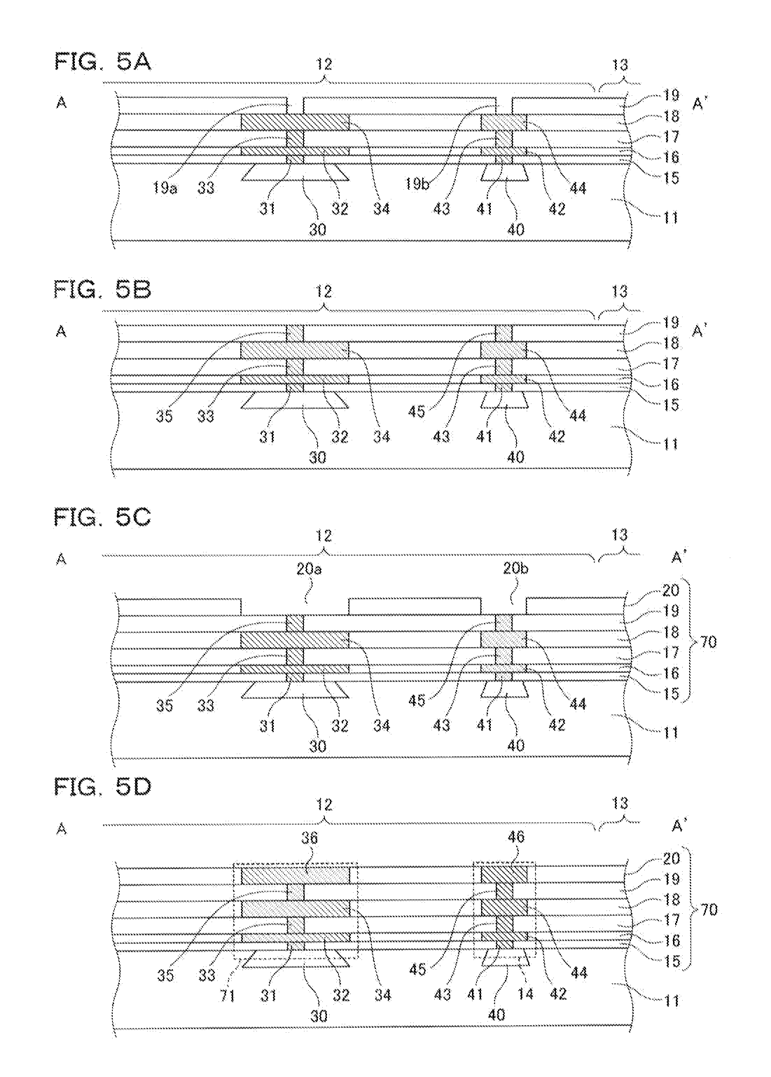

Next, the step of FIGS. 5A to 5D is performed. In these steps, the interlayer insulating film 19 is stacked on the interlayer insulating film 18, the via 35 and the seal via 45 are formed in the interlayer insulating film 19, the interlayer insulating film 20 is stacked on the interlayer insulating film 19, and the wire 36 and the seal wire 46 are formed in the interlayer insulating film 20.

As in the steps of FIGS. 4A to 4D, the interlayer insulating film 19 including a via hole 19a and a groove portion 19b and the interlayer insulating film 20 including a wire groove 20a and a seal wire groove 20b may be formed such that the via hole 19a, the groove portion 19b, the wire groove 20a, and the seal wire groove 20b are filled with conductive films.

Through these steps, the wiring structure 71 including the wires 32, 34, and 36 and the vias 31, 33, and 35 is formed and the seal ring 14 including the seal wires 42, 44, and 46 and the seal vias 41, 43, and 45 is formed.

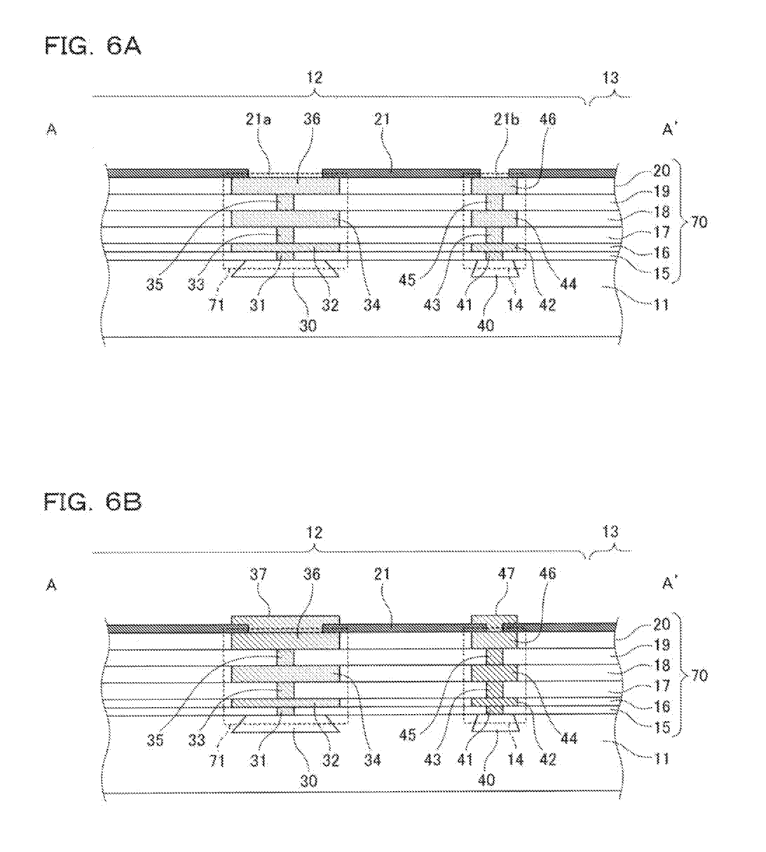

Next, the step of FIG. 6A is performed. First, the passivation film 21 acting as the protective film of the wire 36 and the seal wire 46 is deposited on the wire 36, the top seal wire 46, and the interlayer insulating film 20 in the top wiring layer. After that, the passivation film 21 is partially opened on the wire 36 and the seal wire 46 by lithography and dry etching, so that openings 21a and 21b are formed.

Next, as shown in FIG. 6B, the pad electrode 37 to be connected to the wire 36 is formed on the opening 21a of the passivation film 21 and simultaneously, the cap layer 47 to be connected to the seal wire 46 is formed on the opening 21b of the passivation film 21. To form the pad electrode and the cap layer, first, an Al film is deposited by, e.g., sputtering over the passivation film 21 including the openings 21a and 21b. Subsequently, the Al film is patterned on the wire 36 and the seal wire 46 by lithography and dry etching to form the pad electrode 37 and the cap layer 47.

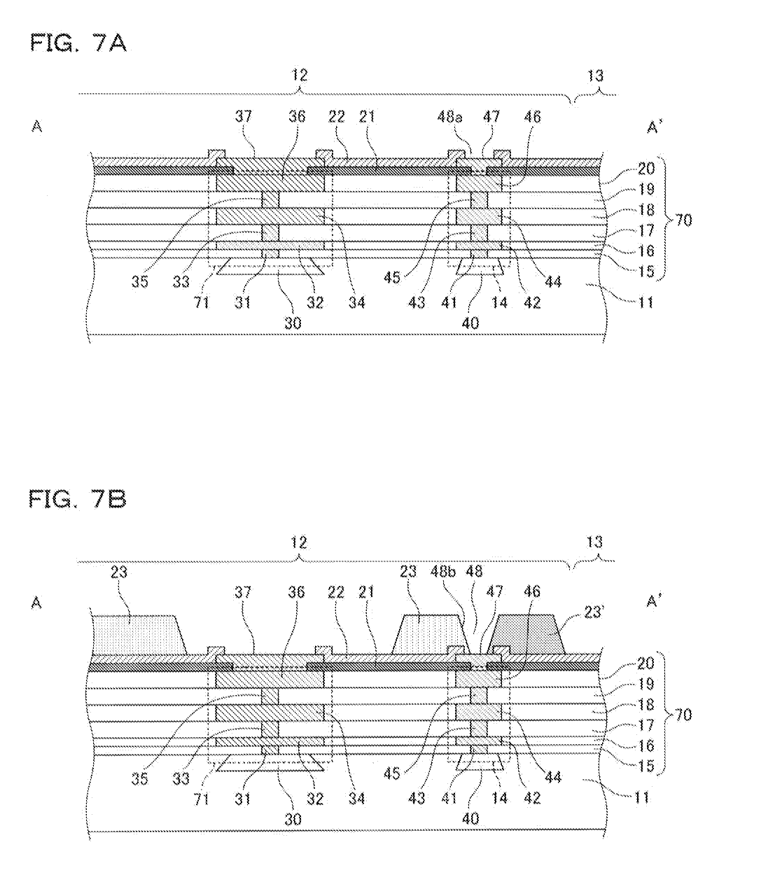

Next, the step of FIG. 7A is performed. First, the other passivation film 22 is deposited on the passivation film 21 so as to cover the pad electrode 37 and the cap layer 47. Subsequently, the passivation film 22 is opened on the pad electrode 37 and the cap layer 47 by lithography and dry etching. Thus a bonding pad is forted on the wiring structure 71 by the pad electrode 37 and an opening 48a is shaped like a closed loop on the cap layer 47 on the seal ring 14.

Next as shown in FIG. 7B, the organic protective films are formed on the chip region 12. First, a liquid resin containing, e.g., polyimide is applied over the substrate 11 by spin coating so as to cover the pad electrode 37 and the seal ring 14. After that, the liquid resin is exposed and developed by lithography to form the organic protective film 23 that is opened on and near the pad electrode 37 of the chip region 12 and on the seal ring 14, and the organic protective film 23′ that is provided in the chip region 12 and between the seal ring 14 and the scribe region 13 so as to surround the internal part of the chip region 12 (see FIG. 1). At this moment, an opening 48b separating the organic protective films 23 and 23′ is shaped like a closed loop on the cap layer 47. Thus the cap layer 47 is partially exposed by the closed-loop opening 48 including the opening 48a of the passivation film.

Subsequently, backside grinding and dicing are performed. First, as shown in FIG. 8A, a protective tape 61 is bonded over the major surface of the substrate 11 (on a surface having the active layer 30 and the organic protective films 23 and 23′). The protective tape 61 is provided to protect the surface during backside grinding and is pressed onto the wafer surface with a sticking roller. At this moment, the organic protective film 23′ is provided like a closed loop between the seal ring 14 and the scribe region 13 and thus the organic protective film 23′ on the periphery of the chip region 12 is brought into contact with the protective tape 61. Therefore, even if a height difference made by the organic protective film 23′ generates a gap partially between the protective tape 61 and the wafer surface, the scribe region 13 and the chip region 12 including the wiring structure 71 are completely separated from each other by the contact portion of the protective tape 61 and the organic protective film 23′.

Next, as shown in FIG. 8B, the substrate 11 is ground from the back side to a predetermined thickness. At this moment, cutting fluid may enter from the scribe region 13 on the outer periphery of the wafer. However, since the organic protective film 23′ is provided as shown in FIG. 8A, the scribe region 13 and the chip region 12 are separated from each other by the contact portion of the organic protective film 23′ and the protective tape 61, preventing contamination by the cutting fluid from reaching the chip region 12. After that, the protective tape 61 is peeled off.

Next, as shown in FIG. 8C, the scribe region 13 is subjected to dicing to separate the chip regions 12 as individual chips, so that the semiconductor devices are obtained. Even if chipping or peeling occurs during dicing, the passivation film 22 and the closed-loop opening 48 formed by the organic protective films 23 and 23′ above the seal ring 14 can prevent damage such as peeling, chipping, and cracks from reaching the element forming region inside the seal ring 14.

As has been discussed, in the method of manufacturing the semiconductor device according to the present embodiment, backside grinding is performed in a state in which the protective tape 61 is in contact with the organic protective film 23′ continuously surrounding the internal part of the chip region 12. Thus there is a gap between the protective tape 61 and the scribe region 13. Even if cutting fluid enters the gap during backside grinding, the cutting fluid does not reach the chip region 12. Although the organic protective films 23 and 23′ create a height difference between the chip region 12 and the scribe region 13, the height difference does not cause contamination on the chip region 12 or cause moisture to damage an internal circuit.

Further, even if chipping or peeling occurs during dicing, the closed-loop opening 48 formed above the seal ring 14 can prevent peeling or damage from reaching the element forming region.

In the foregoing steps, the wires, the vias the seal wires, and the seal vies are formed by planarization (so-called damascene process). The process of the present invention is not limited to planarization and other lamination methods not involving planarization may be used.

In the present embodiment, the three-layer wiring structure and the three-layer seal ring were described. The number of layers is optional.

### Second Embodiment

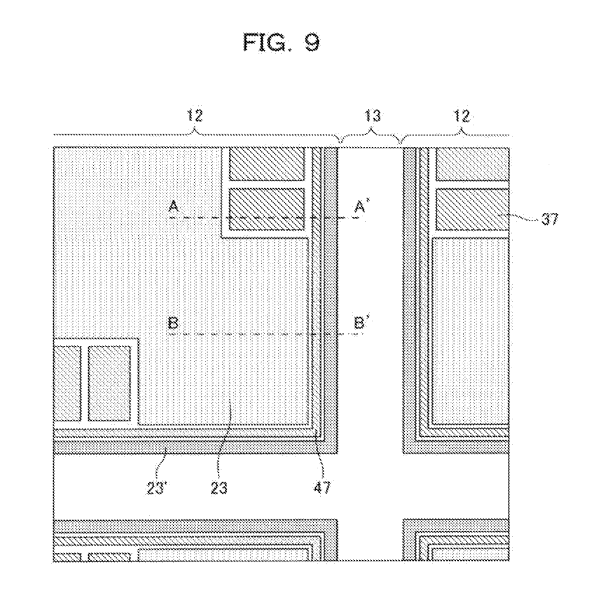

Referring to FIGS. 9 to 11B, a second embodiment will be described below.

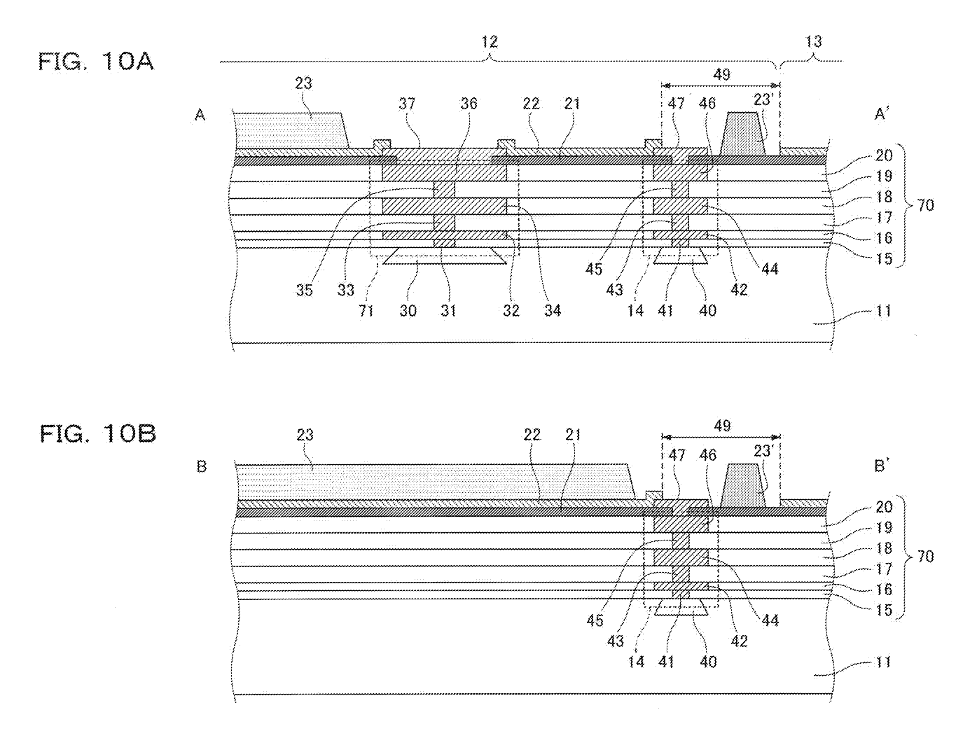

FIG. 9 is a plan view illustrating the principle part of the configuration of a semiconductor device according to the second embodiment. FIG. 9 shows an exemplary semiconductor device according to the present embodiment. FIGS. 10A and 10B are sectional views illustrating the principle part of the configuration of the semiconductor device according to the second embodiment. FIGS. 10A and 10B show sectional structures taken along lines A-A′ and B-B′ of FIG. 9, respectively. As in the first embodiment, a plurality of chip regions 12 and a scribe region 13 for separating the chip regions 12 by dicing are formed on a wafer.

The following will mainly describe differences of the structure of the semiconductor device shown in FIGS. 9, 10A, and 10B from the structure of the first embodiment shown in FIGS. 1, 2A, and 2B. The same constituent elements as in the first embodiment will be indicated by the same reference numerals.

In the present embodiment, as shown in FIGS. 9, 10A, and 10B, a passivation film 22 is formed on a part on a pad electrode 37, a chip region except for a cap layer 47 and an opening 49 closer to the scribe region 13 than the cap layer 47, and the scribe region 13. Further, an organic protective film includes a protective film 23 that is formed on the passivation film 22 so as to have an opening from the pad electrode 37 to a seal ring 14, and a protective film 23′ that is shaped like a closed loop between the cap layer 47 and the scribe region 13 on a passivation film 21. In contrast to the first embodiment, the passivation film 22 is not provided in a region containing the cap layer 47 and reaching the scribe region 13 and the protective film 23 is not formed from the pad electrode 37 to the cap layer 47.

Also in the case where the organic protective films 23 and 23′ are formed thus, contamination caused by cutting fluid on the chip region 12 during backside grinding can be prevented as in the first embodiment. Moreover, the passivation film 22 is separated from the scribe region 13 by the opening 49 near the cap layer 47 and the organic protective films 23 and 23′ are also separated from each other on the seal ring 14. Thus even if chipping or peeling occurs during dicing, the damage or peeling does not reach an element forming region over the seal ring 14.

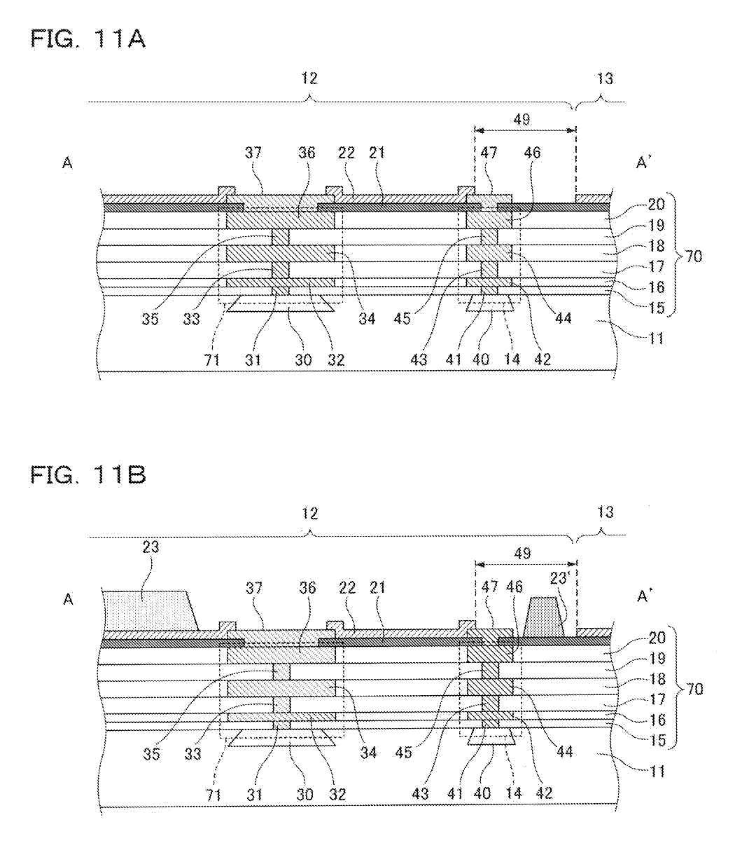

Referring to FIGS. 11A and 11B, the following will describe a manufacturing method for forming this structure. FIGS. 11A and 11B are process sectional views showing the method of manufacturing the semiconductor device according to the second embodiment. The steps of forming the structure are illustrated in cross section taken along line A-A′ of FIG. 9.

First, the structure of FIG. 6B is formed according to the steps of FIGS. 3A to 6B illustrated in the first embodiment. Specifically, an active layer 30, a conductive layer 40, a laminated insulating film 70 including wiring layers 15 to 20, a wiring structure 71, the seal ring 14, the passivation film 21, the pad electrode 37, and the cap layer 47 are formed using a substrate 11. The wiring structure 71 and the seal ring 14 are embedded in the laminated insulating film 70.

Next, the step of FIG. 11A is performed. The other passivation filth 22 is deposited on the passivation film 21 so as to cover the pad electrode 37 and the cap layer 47. Subsequently, by lithography and dry etching, an opening is formed on a part of the pad electrode 37 and the opening 49 is formed on the cap layer 47 and between the cap layer 47 and the scribe region 13. Thus a bonding pad is formed on the wiring structure 71 by the pad electrode 37 and the cap layer 47 on the seal ring 14 is partially exposed through the opening 49.

Next, as shown in FIG. 11B, a liquid resin containing, e.g., polyimide is applied over the substrate 11 by spin coating so as to cover the pad electrode 37 and the cap layer 47. After that, the liquid resin is exposed and developed by lithography to form the organic protective film 23 having an opening from the vicinity of the pad electrode 37 to the seal ring 14 in the chip region 12, and the closed-loop organic protective film 23′ is simultaneously formed between the cap layer 47 and the scribe region 13 on the passivation film 21 so as to surround the internal part of the chip region 12.

After that, as illustrated in FIGS. 8A to 8C of the first embodiment, backside grinding is performed with a bonded protective tape, and dicing is performed to divide the wafer into individual chips.

As has been discussed, also in the present embodiment, the organic protective film 23′ is provided on the periphery of the chip region 12 so as to continuously surround the internal part of the chip region 12. Hence, contamination on the chip region 12 can be prevented during backside grinding.

Further, the cap layer 47 is exposed through the opening 49, and the organic protective film 23′ and the passivation film 22 are separated from each other on the cap layer 47, thereby preventing damage or peeling during dicing from reaching the element forming region.

In the present embodiment, the wires, the vias, the seal wires, and the seal vias are formed by planarization (so-called damascene process). The process of the present invention is not limited to planarization and other lamination methods not involving planarization may be used.

### Third Embodiment

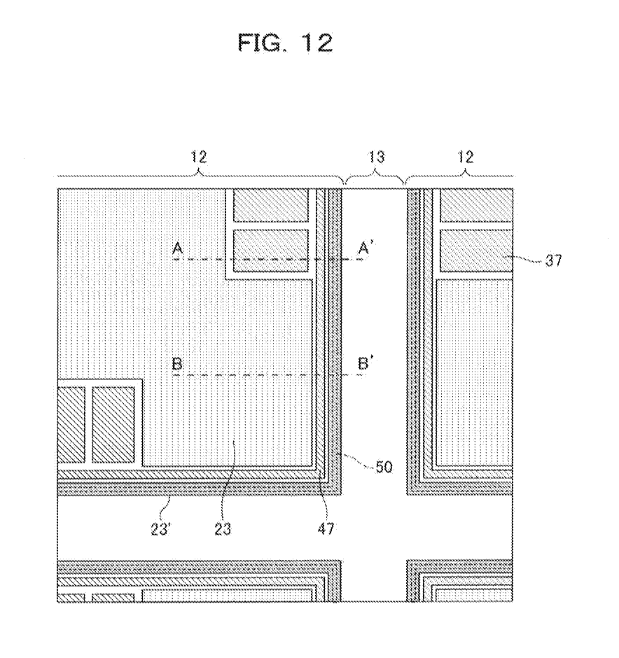

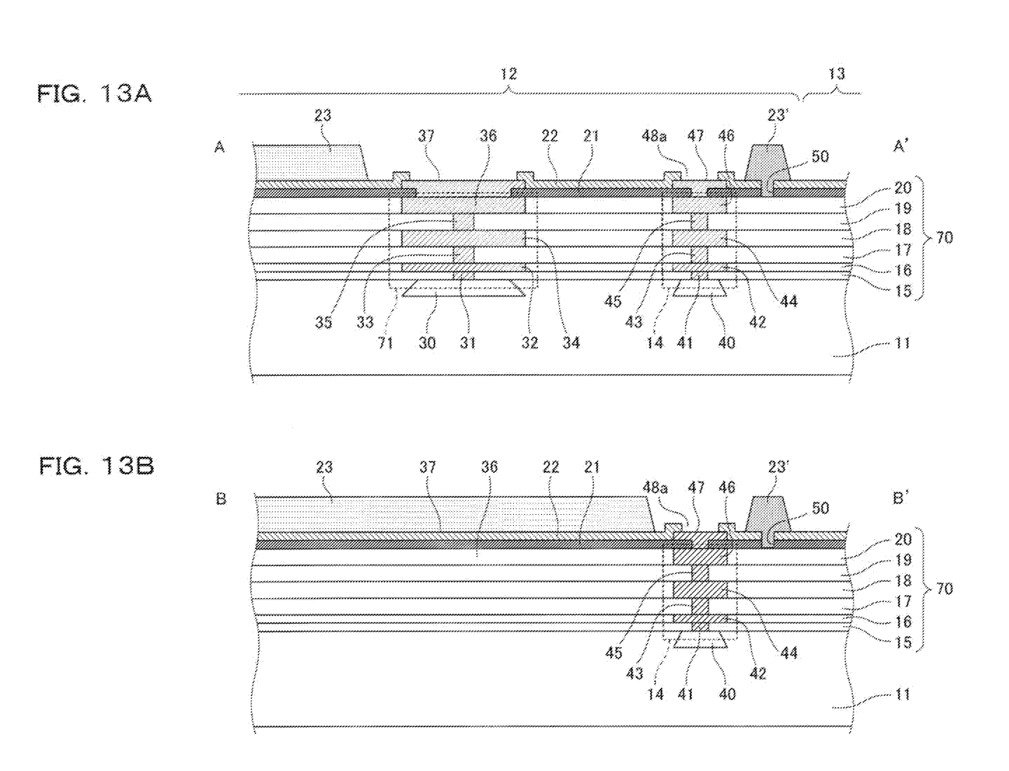

Referring to FIGS. 12 to 14D, a third embodiment will be described below. FIG. 12 is a plan view illustrating the principle part of the configuration of a semiconductor device according to the third embodiment. FIGS. 13A and 13B are sectional views illustrating the principle part of the configuration of the semiconductor device according to the third embodiment. FIGS. 13A and 13B show sectional structures taken along lines A-A′ and B-B′ of FIG. 12, respectively. As in the first embodiment, a plurality of chip regions 12 and a scribe region 13 for separating the chip regions 12 by dicing are formed on a wafer.

The following will mainly describe differences of the structure of the semiconductor device shown in FIGS. 12, 13A, and 13B from the structure of the first embodiment shown in FIGS. 1, 2A, and 2B. The same constituent. elements as in the first embodiment will be indicated by the same reference numerals.

In the present embodiment, as shown in FIGS. 13A and 13B, a passivation film 22 has an opening on a pad electrode 37 and an opening 48a on a cap layer 47. Further; on a passivation film 21 and the passivation film 22, a groove 50 penetrating the passivation films 21 and 22 is shaped like a closed loop between the cap layer 47 and the scribe region 13 in the chip region 12 such that the groove 50 surrounds the internal part of the chip region. The groove 50 is actually invisible in plan view but is illustrated in FIG. 12 for explanation.

In the chip region 12, an organic protective film 23 is formed so as to have an opening from the pad electrode 37 to a seal ring 14, and an organic protective film 23′ is formed outside the cap layer 47 in the chip region 12. At this moment, the groove 50 penetrating the passivation films 21 and 22 is filled with the organic protective film 23′.

Also in the case where the organic protective films 23 and 23′ are formed thus, contamination caused by cutting fluid on the chip region 12 during backside grinding can be prevented as in the first embodiment because the organic protective film 23′ is formed outside the cap layer 47. The passivation film 22 has the continuously surrounding opening 48a on the cap layer 47 and thus even if chipping or peeling occurs during dicing, the damage or peeling does not reach an element forming region. Moreover, the organic protective film 23′ formed between the cap layer 47 and the scribe region 13 covers the continuously surrounding groove 50 formed on the passivation films 21 and 22, and thus even in the case where an interlayer insulating film is a low-dielectric constant film made of a low-k material that may increase the possibility of peeling, peeling of the organic protective film 23′ can be suppressed by the anchor effect, achieving higher reliability.

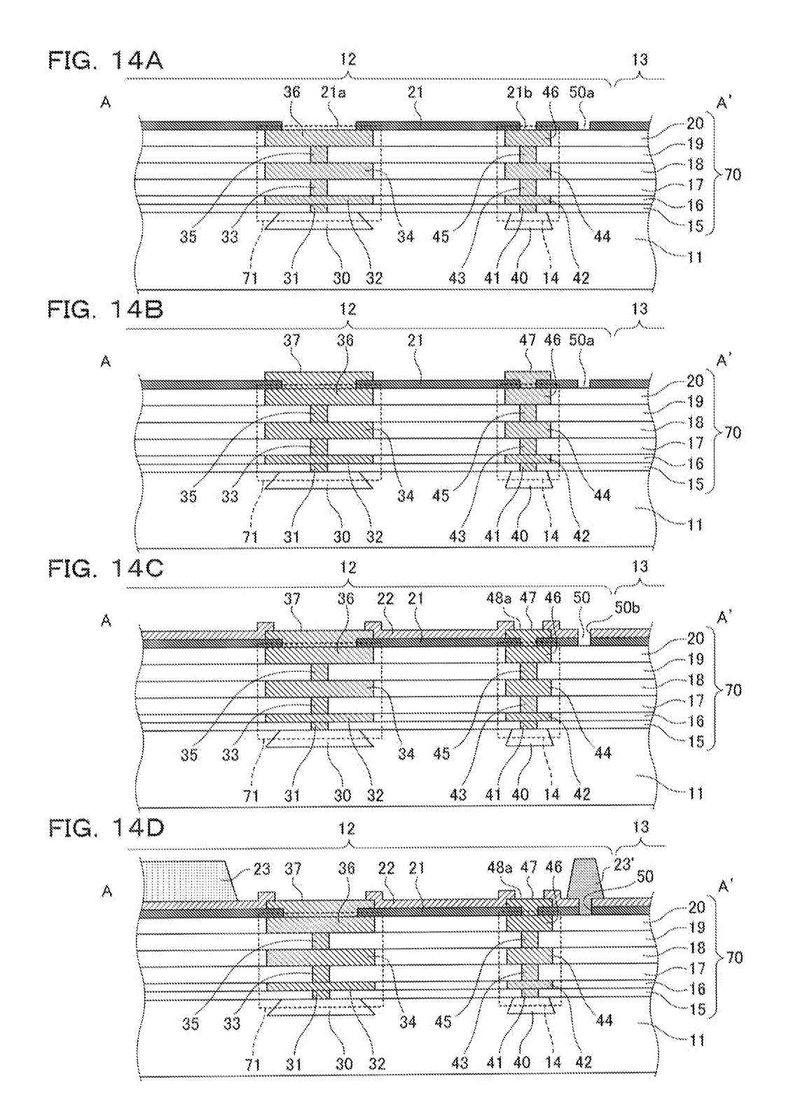

The following will describe a manufacturing method for forming this structure. FIGS. 14A and 14D are process sectional views showing the method of manufacturing the semiconductor device according to the third embodiment. The steps of forming the structure are illustrated in cross section taken along line A-A′ of FIG. 12.

First, the structure of FIG. 5D is formed according to the steps of FIGS. 3A to 5D illustrated in the first embodiment. Specifically, an active layer 30, a conductive layer 40, a laminated insulating film 70 including wiring layers 15 to 20, a wiring structure 71, and the seal ring 14 are formed using a substrate 11. The wiring structure 71 and the seal ring 14 are embedded in the laminated insulating film 70.

Next, the step of FIG. 14A is performed. First, on the interlayer insulating film 20 that includes a wire 36 and a seal wire 46 in the top wiring layer, the passivation film 21 is deposited as the protective film of the wire 36. After that, the passivation film 21 is partially opened on the wire 36 and the seal wire 46 by lithography and dry etching, so that an opening 21a and an opening 21b are formed. At the same time, a closed-loop groove 50a is formed between the seal ring 14 and the scribe region 13 in the chip region 12 such that the groove 50a surrounds the internal part of the chip region 12 and reaches the interlayer insulating film 20.

Next, as shown in FIG. 14B, the pad electrode 37 to be connected to the wire 36 is formed on the opening 21a of the passivation film 21 and the cap layer 47 to be connected to the seal wire 46 is formed on the opening 21b of the passivation film 21. To form the pad electrode and the cap layer, first, an Al film is deposited by, e.g., sputtering over the passivation film 21 including the openings 21a and 21b. Subsequently, the Al film is patterned on the wire 36 and the seal wire 46 by lithography and dry etching to form the pad electrode 37 and the cap layer 47.

Next, the step of FIG. 14C is performed. First, the other passivation film 22 is deposited on the passivation film 21 so as to cover the pad electrode 37 and the cap layer 47 in the chip region 12. Subsequently, the passivation film 22 is opened on the pad electrode 37 and the cap layer 47 by lithography and dry etching, and simultaneously, a closed-loop groove 50b is formed on the closed-loop groove 50a on the passivation film 21. Thus a bonding pad is formed by the pad electrode 37 on the wiring structure 71, the opening 48a is formed on the cap layer, and the closed-loop groove 50 is formed that surrounds the internal part of the chip region 12 and penetrates the passivation films 21 and 22.

Next, the step of FIG. 14D is performed. First, a liquid resin containing, e.g., polyimide is applied over the substrate 11 by spin coating so as to cover the pad electrode 37, the cap layer 47, and the closed-loop groove 50. After that, the liquid resin is exposed and developed by lithography to form the organic protective film 23 having an opening from the vicinity of the pad electrode 37 to the seal ring in the chip region 12, and the closed-loop organic protective film 23′ is formed between the seal ring 14 in the chip region 12 and the scribe region 13 so as to surround the internal part of the chip region 12 and cover the closed-loop groove 50.

After that, as illustrated in FIGS. 8A to 8C of the first embodiment, backside grinding is performed with a bonded protective tape and dicing is performed to divide the wafer into individual chips.

As has been discussed, also in the present embodiment, the organic protective film 23′ is provided along the outer periphery of the chip region 12 so as to continuously surround the internal part of the chip region 12, thereby preventing contamination on the chip region 12 during backside grinding.

Since the passivation film 22 has the closed-loop opening 48a on the cap layer 47, even if chipping or peeling occurs during dicing, the damage or peeling does not reach the element forming region.

Further, the organic protective film 23′ formed between the cap layer 47 and the scribe region 13 covers the closed-loop groove 50 formed on the passivation films 21 and 22, and thus peeling of the organic protective film 23′ can be suppressed by the anchor effect. Peeling of the organic protective film 23′ can be suppressed during dicing not only in the case where dicing is performed after backside grinding as in the present embodiment but also in the case where a groove is formed in the scribe region 13 by DBG process before backside grinding, thereby suppressing contamination caused by cutting fluid on the chip region 12 in the subsequent backside grinding and improving manufacturing yields.

In the present embodiment, the wires, the vias, the seal wires, and the seal vias are formed by planarization (so-called damascene process). The process of the present invention is not limited to planarization and other lamination methods not involving planarization may be used.

### Fourth Embodiment

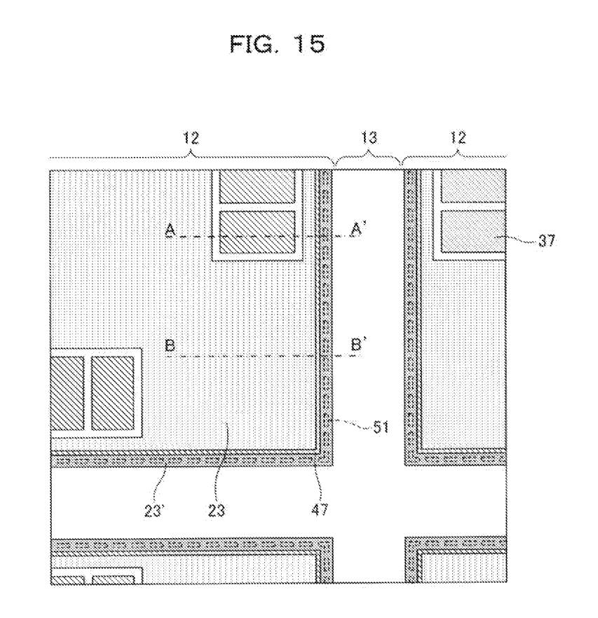

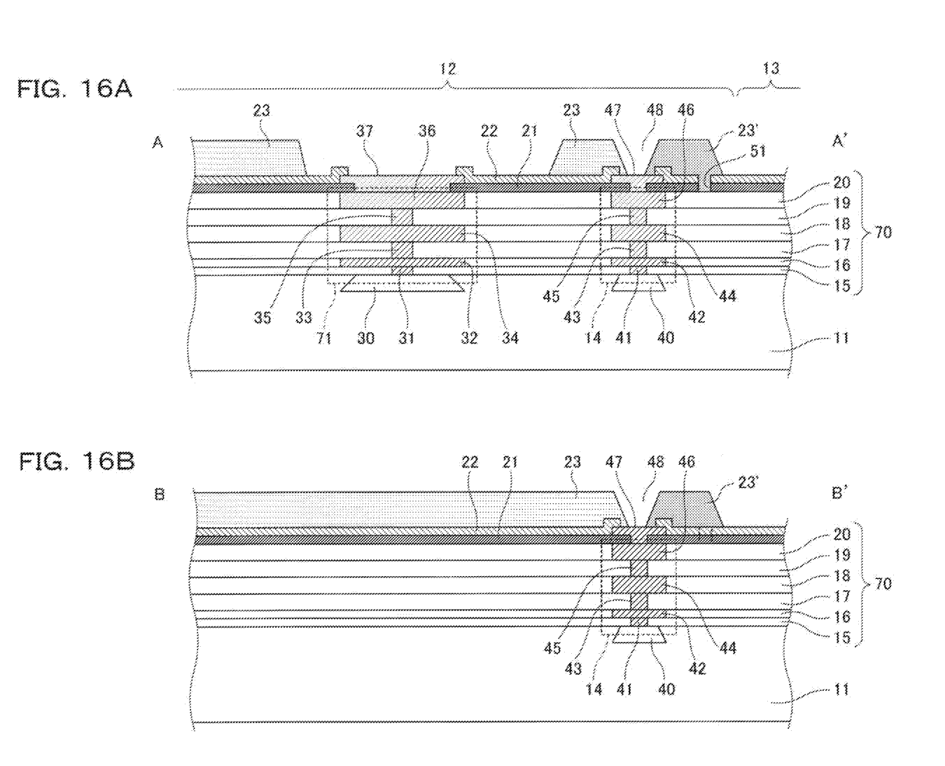

A fourth embodiment will be described below. FIG. 15 is a plan view illustrating the principle part of the configuration of a semiconductor device according to the fourth embodiment. FIGS. 16A and 16B are sectional views illustrating the principle part of the configuration of the semiconductor device according to the fourth embodiment. FIGS. 16A and 16B show sectional structures taken along lines A-A′ and B-B′ of FIG. 15, respectively. As in the first to third embodiments, a plurality of chip regions 12 and a scribe region 13 for separating the chip regions 12 by dicing are formed on a wafer.

The following will mainly discuss differences of the structure of the present embodiment in FIGS. 15, 16A, and 16B from the structure of the third embodiment in FIGS. 12, 13A, and 13B. The same constituent elements will be indicated by the same reference numerals.

In the third embodiment of FIGS. 12, 13A, and 13B, the closed-loop groove 50 is formed between the seal ring 14 and the scribe region 13 on the passivation films 21 and 22 so as to surround the internal part of the chip region 12, whereas in the present embodiment, as shown in FIGS. 15, 16A, and 16B, a plurality of openings 51 are formed that are not shaped like closed loops but are combined substantially into a rectangle surrounding the internal part of the chip region 12, penetrate passivation films 21 and 22, and are unconnected to one another. The openings 51 are actually invisible in plan view but are illustrated in FIG. 15 for explanation.

In the chip region 12, an organic protective film 23 is formed so as to be opened on and near a pad electrode 37 and on a seal ring 14. Further, an organic protective film 23′ is formed outside a cap layer 47 in the chip region 12. At this moment, the openings 51 penetrating the passivation films 21 and 22 are filled with the organic protective film 23′. A difference from the third embodiment is that the organic protective film 23 is formed also between the pad electrode 37 and the seal ring 14 and the organic protective films 23 and 23′ form a closed-loop opening 48 on the cap layer 47.

Also in the case where the organic protective film 23′ is formed thus, it is possible to prevent cutting fluid from contaminating the chip region 12 during backside grinding, and the closed-loop opening 48 can suppress development of damage or peeling into an element forming region during dicing. Further, the openings 51 penetrating the passivation films 21 and 22 are covered with the organic protective film 23′, further suppressing peeling of the organic protective film 23′. Moreover, the openings 51 are unconnected to One another, so that even if the organic protective film 23′ peels off, the development of peeling along the periphery of a chip can be suppressed.

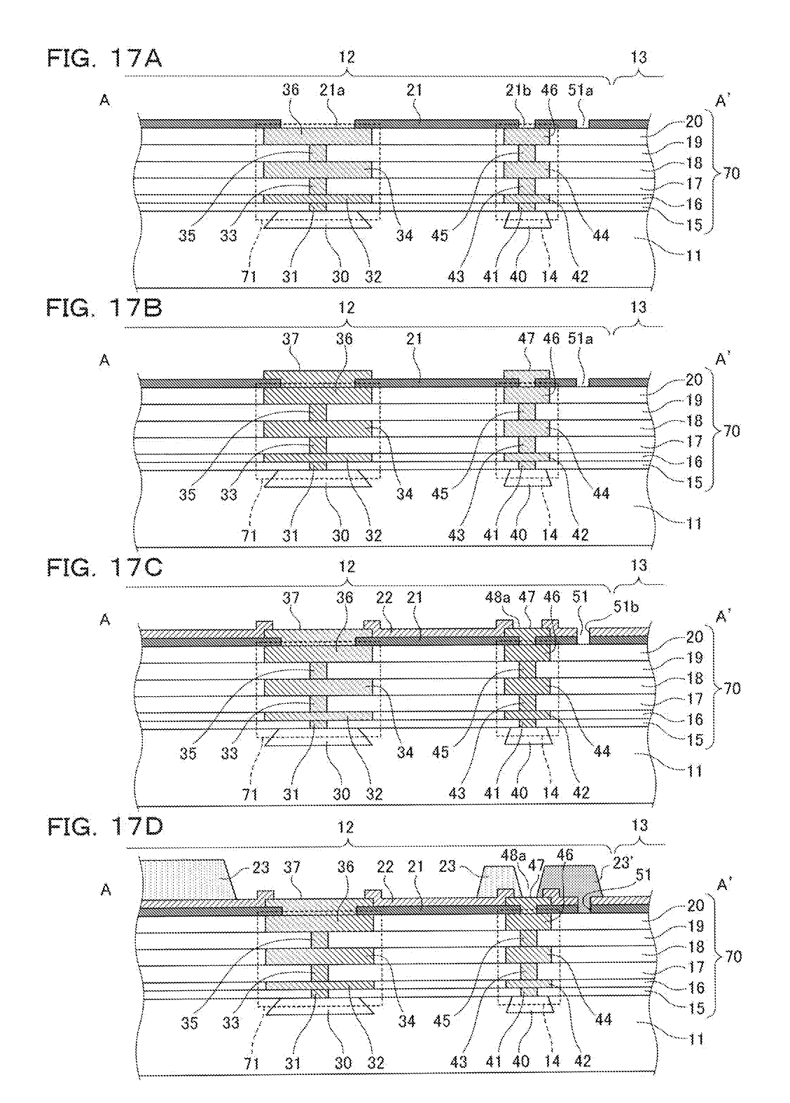

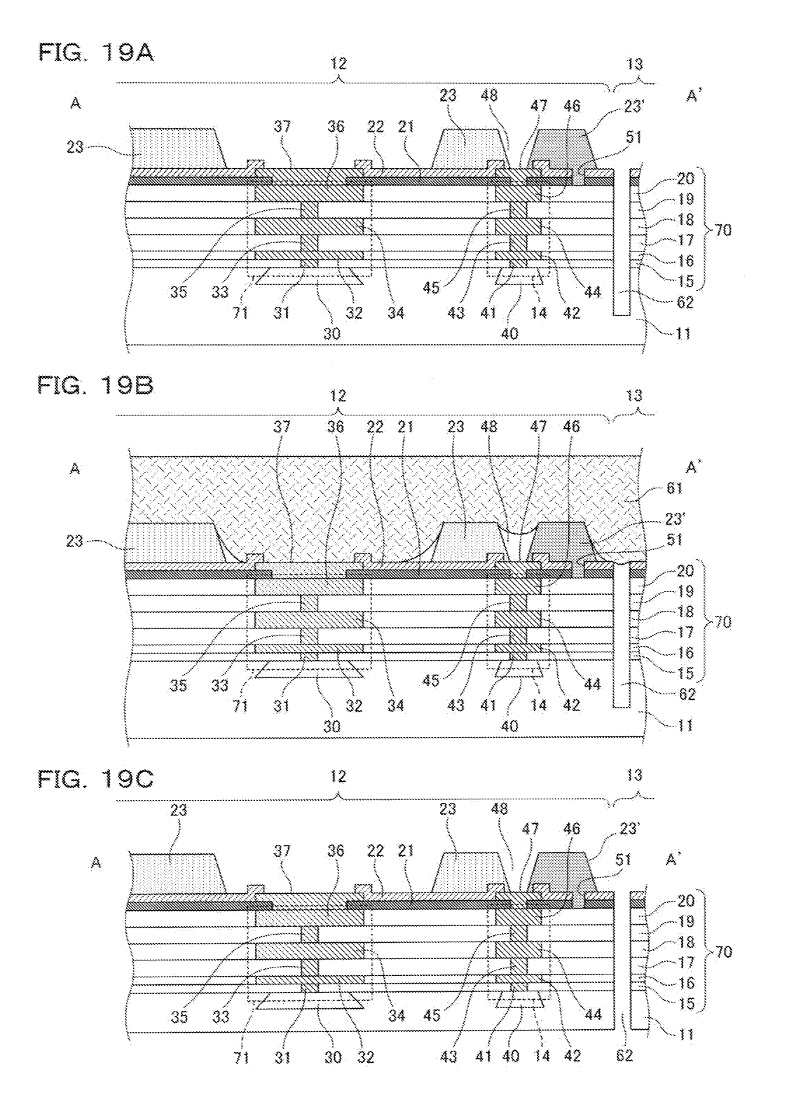

The following will describe a manufacturing method for forming this structure. FIGS. 17A to 17D, 18A to 18D, and 19A to 19C are process sectional views showing the method of manufacturing the semiconductor device according to the fourth embodiment. The steps of forming the structure are illustrated in cross section taken along lines A-A′ and B-B′ of FIG. 15, respectively. FIGS. 19A to 19C are explanatory drawings showing, in particular, backside grinding and dicing.

First, the structure of FIG. 5D is formed according to the steps of FIGS. 3A to 5D described in the first embodiment. Specifically, an active layer 30, a conductive layer 40, a laminated insulating film 70 including interlayer insulating films 15 to 20, a wiring structure 71, and the seal ring 14 are formed using a substrate 11. The wiring structure 71 and the seal ring 14 are embedded in the laminated insulating film 70.

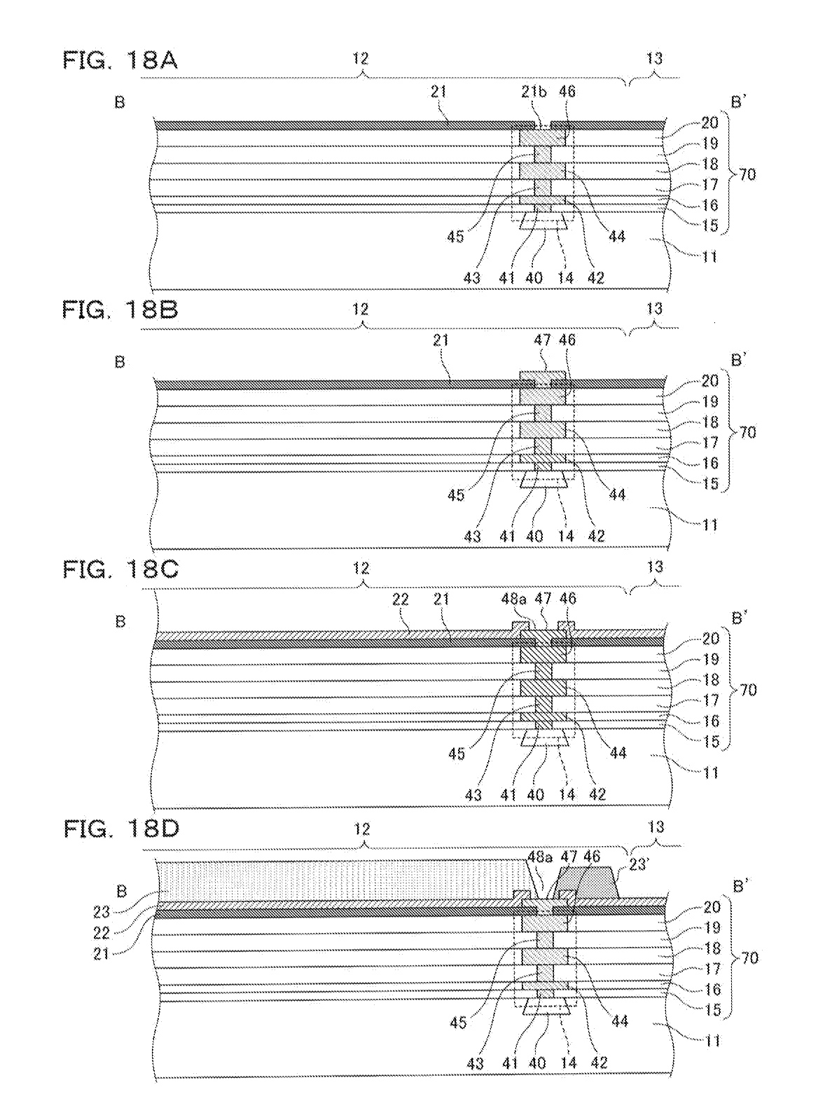

Next, the step of FIGS. 17A and 18A is performed. First, the passivation film 21 acting as the protective film of a wire 36 is deposited on the interlayer insulating film 20 including the wire 36 and a seal wire 46 in the top wiring layer. After that, the passivation film 21 is partially opened on the wire 36 and the seal wire 46 by lithography and dry etching, so that openings 21a and 21b are formed. Simultaneously, multiple openings 51a are formed at regular intervals between the seal ring 14 and the scribe region 13 in the chip region 12 such that the openings 51a are combined so as to surround the internal part of the chip region and reach the interlayer insulating film 20. FIG. 17A shows the cross section of a part including the Opening 51a. FIG. 18A shows the cross section of a part not including the opening 51a.

Next, as shown in FIGS. 17B and 18B, the pad electrode 37 to be connected to the wire 36 is formed on the opening 21a of the passivation film 21 and the cap layer 47 to be connected to the seal wire 46 is formed on the opening 21b of the passivation film 21. To form the pad electrode and the cap layer, first, an Al film is deposited by, e.g., sputtering over the passivation film 21 including the openings 21a and 21b. Subsequently, the Al film is patterned on the wire 36 and the seal wire 46 by lithography and dry etching to form the pad electrode 37 and the cap layer 47.

Next, the step of FIGS. 17C and 18C is performed. First, the other passivation film 22 is deposited on the passivation film 21 so as to cover the pad electrode 37 and the cap layer 47 in the chip region 12. Subsequently, the passivation film 22 is opened on the pad electrode 37 and the cap layer 47 by lithography and dry etching and simultaneously, multiple openings 51b are formed on the respective openings 51a formed on the passivation film 21. FIG. 17C shows the cross section of a part including the opening 51b. FIG. 18C shows the cross section of a part not including the opening 51b. Thus a bonding pad is formed on the wiring structure 71 by the pad electrode 37, an opening 48a is formed on the cap layer 47, and the openings 51 are formed that are combined substantially into a rectangle surrounding the internal part of the chip region 12, penetrate the passivation films 21 and 22, and are unconnected to one another.

Next, the step of FIGS. 17D and 18D is performed. First, a liquid resin containing, e.g., polyimide is applied by spin coating over the substrate 11 so as to cover the pad electrode 37, the cap layer 47, and the openings 51. After that, the liquid resin is exposed and developed by lithography to form the organic protective film 23 that is opened near the pad electrode 37 of the chip region 12 and on the seal ring 14, and the organic protective film 23′ that is disposed between the seal ring 14 in the chip region 12 and the scribe region 13 so as to surround the internal part of the chip region 12 and cover the openings 51 combined substantially into a rectangle.

As shown in FIGS. 19A to 19C, the chip regions 12 formed on the wafer are separated as individual semiconductor devices. This, method is called dicing before grinding (DBG) process (or predicing). FIGS. 19A to 19C show a cross-sectional structure taken along line A-A′ of FIG. 15.

First, as shown in FIG. 19A, the substrate 11 is cut partially from the major surface along the scribe region 13 to form a groove 62.

Next, as shown in FIG. 19B, a protective tape 61 is bonded on the major surface of the substrate 11.

Subsequently, as shown in FIG. 19C, the substrate 11 is ground from the back side to reach the groove 62. Thus the chip regions 12 are separated as individual semiconductor devices. After that, the protective tape 61 is peeled off to obtain the semiconductor devices.

As has been discussed, also in the semiconductor device and the method of manufacturing the same according to the present embodiment, the organic protective film 23′ is provided on the periphery of the chip region 12 so as to continuously surround the internal part of the chip region 12. Further, the organic protective-film 23′ fills the openings 51 penetrating the passivation films 21 and 22. Thus when the substrate 11 is cut along the scribe region 13, the anchor effect of the openings 51 suppresses peeling of the organic protective film 23′ and the organic protective film 23′ reliably suppresses the entry of cutting fluid into an element forming region during the subsequent backside grinding, thereby preventing contamination of the chip region 12. This configuration is also applicable to the case where dicing is performed after backside grinding.

In the present embodiment, the wires, the vias, the seal wires, and the seal vias are formed by planarization (so-called damascene process). The process of the present invention is not limited to planarization and other lamination methods not involving planarization may be used.

### Fifth Embodiment

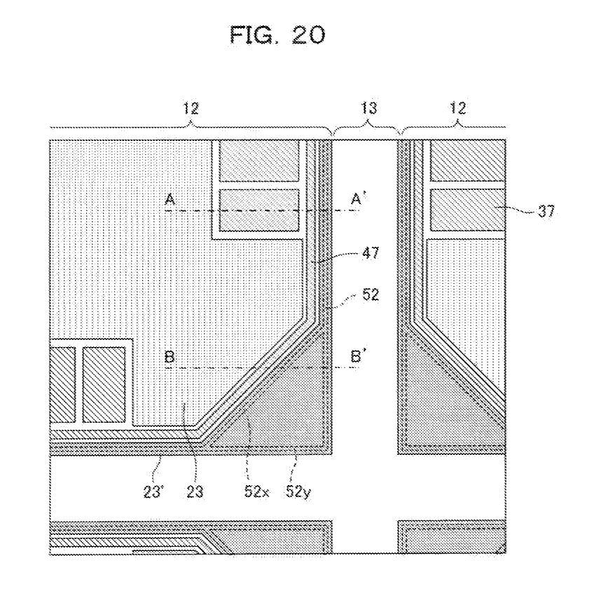

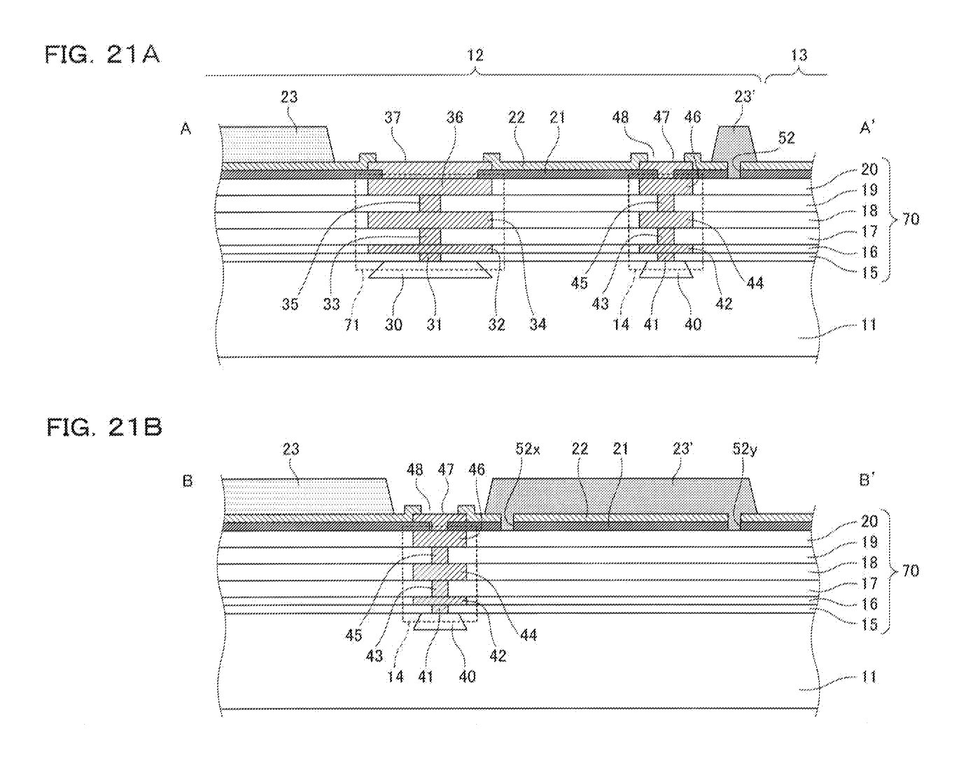

A fifth embodiment will be described below. FIG. 20 is a plan view illustrating the principle part of the configuration of a semiconductor device according to the fifth embodiment. FIGS. 21A and 21B are sectional views illustrating the principle part of the configuration of the semiconductor device according to the fifth embodiment. FIGS. 21A and 21B show sectional structures taken along lines A-A′ and B-B′ of FIG. 20, respectively. As in the first to fourth embodiments, a plurality of chip regions 12 and a scribe region 13 for separating the chip regions 12 by dicing are formed on a wafer.

The following will mainly describe differences of the structure of the semiconductor device shown in FIGS. 20, 21A, and 21B from the structure of the third embodiment shown in FIGS. 12, 13A, and 13B. The same constituent elements will be indicated by the same reference numerals.

As shown in FIG. 20, unlike in the third embodiment, a seal ring 14 in the present embodiment is not rectangular but is octagonal in plan view as if chip corners were chamfered. Specifically, at the center of each side of the chip region 12, the seal ring 14 is formed in parallel with the scribe region 13. At each of the corners of the chip region 12, the seal ring 14 is formed so as to connect the ends of two sides of the chip region 12, so that the octagonal seal ring 14 is formed. In the third embodiment, the groove 50 penetrating the passivation films 21 and 22 is a continuous rectangle that is formed between the seal ring 14 of the chip region 12 and the scribe region 13 so as to surround the internal part of the chip region 12, whereas in the present embodiment, a groove 52 penetrating passivation films 21 and 22 at a corner of a chip is divided into a region 52x parallel to the seal ring and a region 52y parallel to the scribe region 13. The groove 52 forms a closed-loop surrounding the internal part of the chip region 12 and the grooves 52x and 52y form a continuous triangular opening at a corner of the chip region 12. Further, in the third embodiment, the organic protective film 23′ is formed into a continuous rectangle of equal width so as to fill the groove 50 penetrating the passivation films 21 and 22, whereas in the present embodiment, an organic protective film 23′ fills the groove 52x parallel to the seal ring 14 and the groove 52y parallel to the scribe region 13 so as to substantially form a triangle at a corner of a chip. In Other words, the organic protective film 23′ substantially covers the entire region between the seal ring 14 in the chip region 12 and the scribe region 13, including the closed-loop groove 52.

Also in this configuration, the organic protective film 23′ substantially formed into a triangle at a corner of a chip can increase the adhesion of a protective tape during backside grinding and prevent cutting fluid from contaminating the chip region 12 during backside grinding. Further, although a corner of a chip is susceptible to chipping or breakage during dicing, chipping or peeling in dicing does not damage an element forming area because an opening 48 is provided on a cap layer 47 and the organic protective film 23′ covers the closed-loop groove 52. Moreover, although damage or peeling is likely to occur at a corner of a chip, the organic protective film 23′ covering the grooves 52x and 52y effectively suppresses peeling and curling at the corner, thereby improving yields and the reliability of the product.

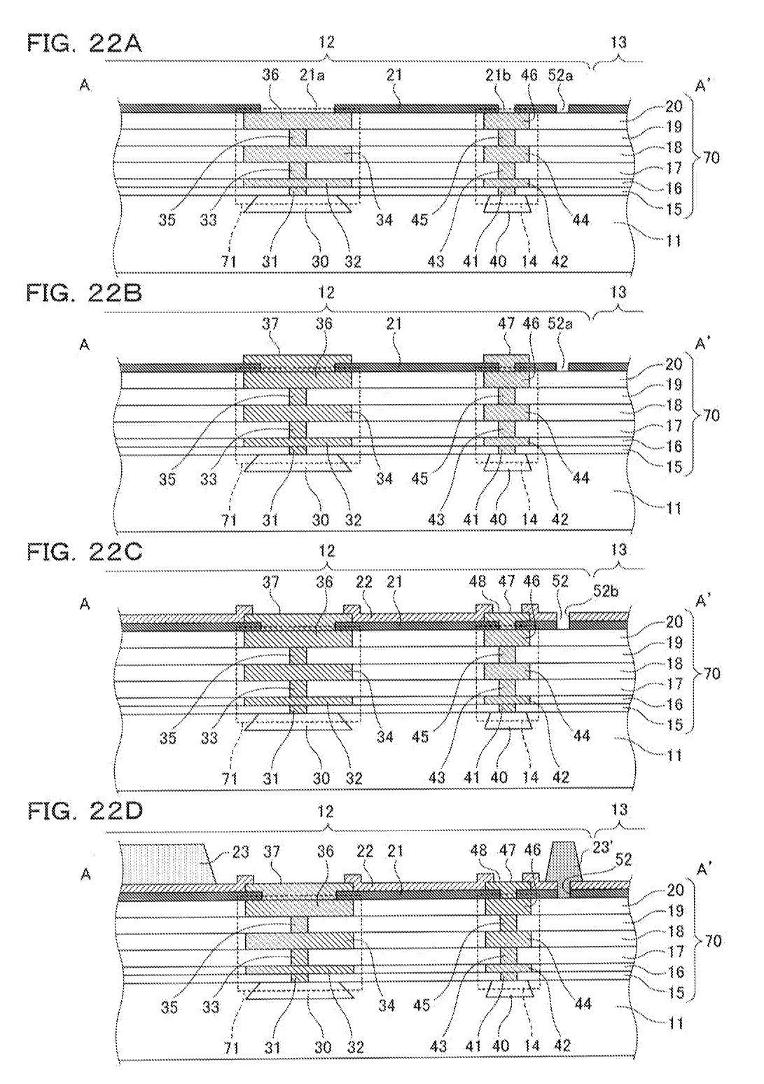

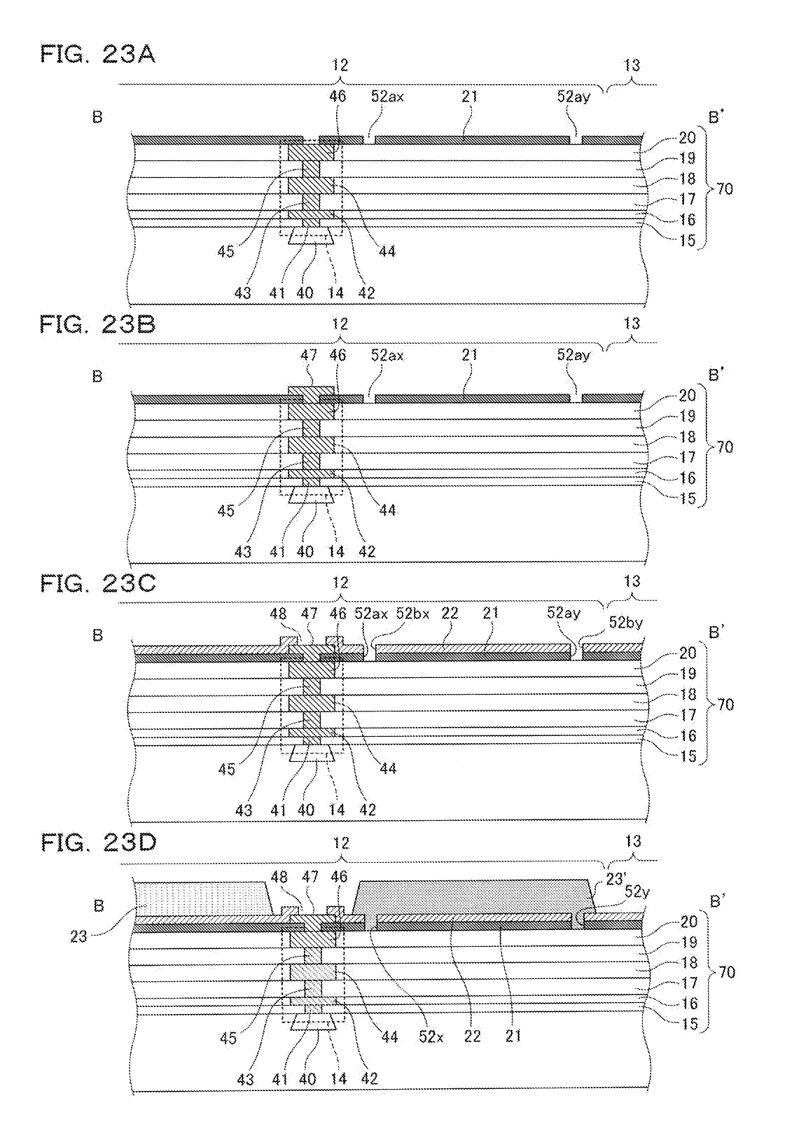

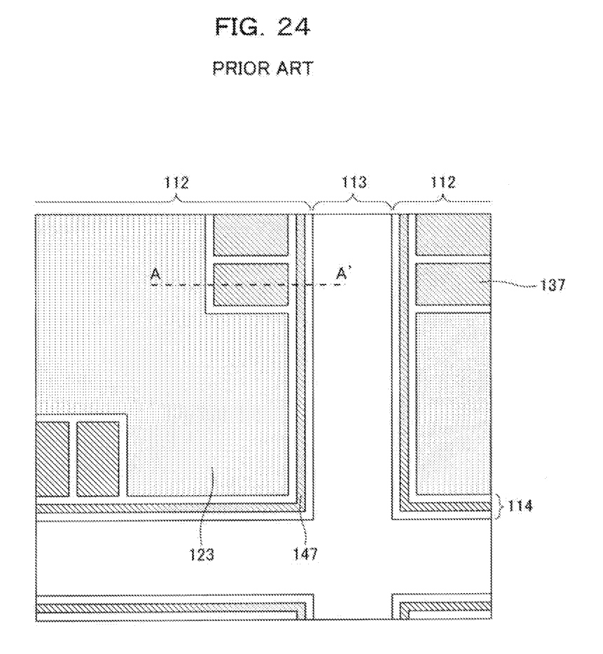

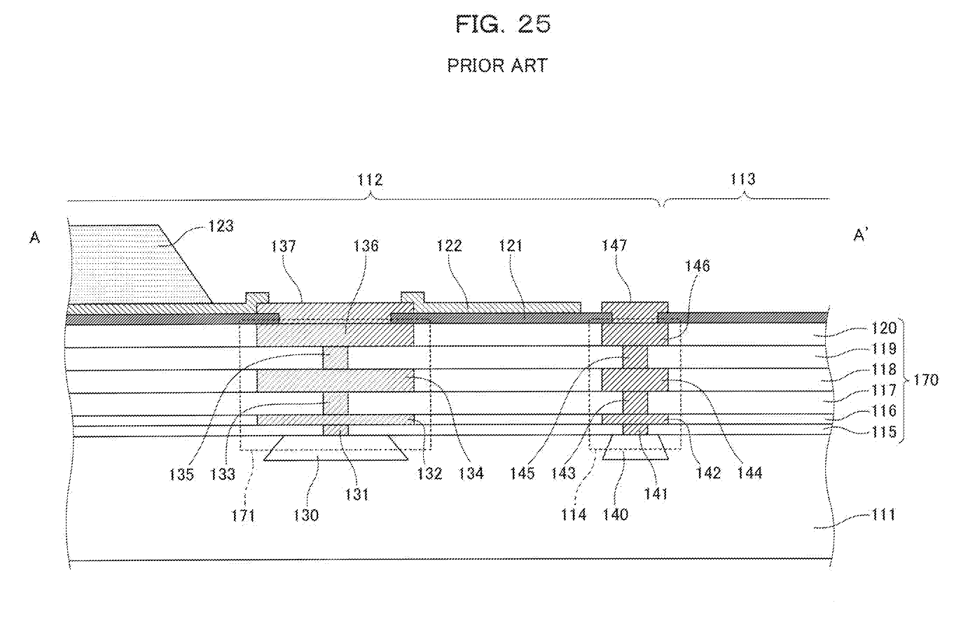

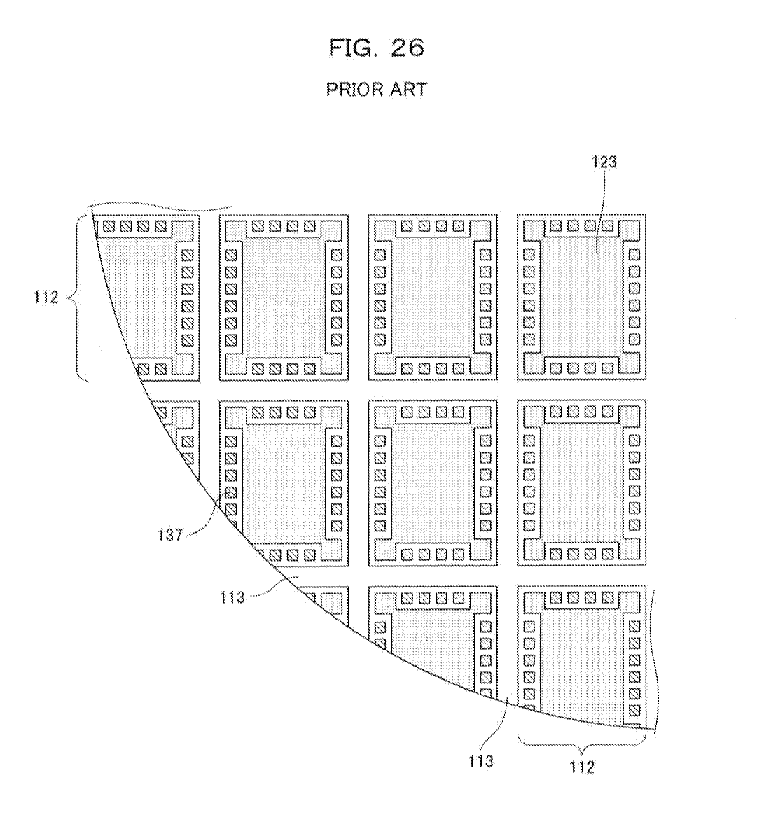

The following will describe a manufacturing method for forming this structure. FIGS. 22A to 22D and 23A to 23D are process sectional views showing the method of manufacturing the semiconductor device according to the fifth embodiment. The steps of forming the structure are illustrated in cross section taken along lines A-A′ and B-B′ of FIG. 20.

First, the structure of FIG. 5D is formed according to the steps of FIGS. 3A to 5D illustrated in the first embodiment. Specifically, an active layer 30, a conductive layer 40, a laminated insulating film 70 including wiring layers 15 to 20, a wiring structure 71, and the seal ring 14 are formed using a substrate 11. The wiring structure 71 and the seal ring 14 are embedded in the laminated insulating film 70. In the present embodiment, the position of the seal ring at a corner of a chip is different from those of FIGS. 3A to 5D but the seal ring is fabricated as in the first embodiment.

Next, the step of FIGS. 22A and 23A is performed. First, the passivation film 21 acting as the protective film of a wire 36 is deposited on the interlayer insulating film 20 including the wire 36 and a seal wire 46 in the top wiring layer. After that, the passivation film 21 is partially opened on the wire 36 and the seal wire 46 by lithography and dry etching, so that openings 21a and 21b are formed. Simultaneously, grooves. 52a, 52ax, and 52ay that surround the internal part of the chip region and reach the interlayer insulating film 20 are formed like closed loops between the seal ring 14 in the chip region 12 and the scribe region 13. At this moment, the groove 52a and the groove 52ay form a closed-loop groove substantially shaped like a rectangle and the groove 52a and the groove 52ax form a closed-loop groove substantially shaped like an octagon.

Next, as shown in FIGS. 22B and 23B, a pad electrode 37 to be connected to the wire 36 is formed on the opening 21a of the passivation film 21 and the cap layer 47 to be connected to the seal wire 46 is formed on the opening 21b of the passivation film 21. To form the pad electrode and the cap layer, first, an Al film is deposited by, e.g., sputtering over the passivation film 21 including the openings 21a and 21b. Subsequently, the Al film is patterned on the wire 36 and the seal wire 46 by lithography and dry etching to form the pad electrode 37 and the cap layer 47.

Next, the step of FIGS. 22C and 23C is performed. First, the other passivation film 22 is deposited on the passivation film 21 so as to cover the pad electrode 37 and the cap layer 47 in the chip region 12. Subsequently, the passivation film 22 is opened on the pad electrode 37 and the cap layer 47 by lithography and dry etching and simultaneously, grooves 52b, 52bx, and 52by are formed on the grooves 52a, 52ax, and 52ay formed like closed loops on the passivation film 21. Thus a bonding pad is formed on the wiring structure 71 by the pad electrode 37, the opening 48 is formed on the cap layer 47, and the closed-loop grooves 52, 52x, and 52y are formed that surround the internal part of the chip region 12 and penetrate the passivation films 21 and 22. At this moment, the grooves 52 and 52y form a closed-loop groove substantially shaped like a rectangle and the grooves 52 and 52x form a closed-loop groove substantially shaped like an octagon.

Next, the step of FIGS. 22D and 23D is performed. First, a liquid resin containing, e.g., polyimide is applied over the substrate 11 by spin coating so as to cover the pad electrode 37, the cap layer 47, and the closed-loop grooves 52, 52k, and 52y. After that, the liquid resin is exposed and developed by lithography to form an organic protective film 23 that is opened from the vicinity Of the pad electrode 37 to the seal ring 14 in the chip region 12 and the organic protective film 23′ that is formed between the seal ring 14 in the chip region 12 and the scribe region 13 so as to surround the internal part of the chip region and cover the closed-loop grooves 52, 52x, and 52y. At this moment, the organic protective film 23′ covers a triangular region formed by the groove 52x and the groove 52y at a corner of a chip and is substantially shaped like a triangle as shown in FIG. 20.

After that, as has been illustrated in FIGS. 8A to 8C according to the first embodiment, a protective tape 61 is bonded, backside grinding is performed, and then the wafer is diced into individual semiconductor devices.

This manufacturing method can form the organic protective film 23′ that suppresses peeling at a corner of a chip, without increasing the number of steps. Thus it is possible to suppress contamination caused by cutting fluid on the chip region during backside grinding and prevent damage or peeling during dicing from reaching an element forming region, thereby fabricating semiconductor devices with reinforced chip corners.

The explanation described the five specific examples of the technique of the present invention. The present invention is not limited to these examples and various changes can be made without departing from the purport of the configuration.

For example, in the foregoing embodiments, the organic protective film is a polyimide film but the material of the film is not particularly limited. Materials such as polybenzoxazole (PBO) may be used.

In the fourth embodiment, predicing was described. Predicing may be used in other embodiments. Further, in the fourth embodiment, dicing may be performed after backside grinding.

In the explanation, the protective film 23′ is not formed on the openings of the passivation films 21 and 22 in some of the embodiments. The protective film 23′ may be formed on the openings of the passivation films 21 and 22 also in these embodiments. Further, the grooves under the protective film 23′ may be discontinuously formed in all of the embodiments. In the explanation, the protective film 23 is not formed between the pad electrode 37 and the cap layer 47 in some of the embodiments. The formation of the protective film 23 is optional in all of the embodiments.

What is claimed is:

1. A semiconductor device comprising:
a semiconductor substrate;
an electrode pad formed on the semiconductor substrate;
a seal ring formed between the electrode pad and an outer periphery of the semiconductor substrate;
a cap layer formed on the seal ring, the cap layer being connected to the seal ring;
a passivation film formed on the semiconductor substrate so as to expose the electrode pad and the cap layer;
a first protective film formed on the passivation film and inside the seal ring so as to expose the electrode pad and the cap layer; and
a second protective film formed on the passivation film and outside the seal ring so as to expose the cap layer.

2. The semiconductor device according to claim 1, further comprising a first groove formed between the cap layer of the passivation film and the outer periphery of the semiconductor substrate, the first groove being shaped like a closed loop in parallel with the outer periphery of the semiconductor substrate,
wherein the second protective film is formed also in the first groove.

3. The semiconductor device according to claim 1, further comprising a plurality of openings formed between the cap layer of the passivation film and the outer periphery of the semiconductor substrate, the openings being formed at intervals in parallel with the outer periphery of the semiconductor substrate,
wherein the second protective film is formed also in the openings.

4. The semiconductor device according to claim 1, wherein the seal ring is octagonal in plan view and has a side at each corner of the semiconductor substrate.

5. The semiconductor device according to claim 4, further comprising:
a first groove formed between the cap layer of the passivation film and the outer periphery of the semiconductor substrate, the first groove being shaped like a closed loop in parallel with the outer periphery of the semiconductor substrate; and
a second groove that is parallel to the seal ring at each corner of a chip region and is connected to the first groove at each end,
wherein the second protective film is formed also in the first groove and the second groove and covers a triangle formed by the first groove and the second groove.

6. The semiconductor device according to claim 4, further comprising:
a plurality of first openings formed between the cap layer of the passivation film and the outer periphery of the semiconductor substrate, the first openings being formed at intervals in parallel with the outer periphery of the semiconductor substrate; and
a plurality of second openings that are parallel to the seal ring at each corner of a chip region, are combined to be connected to the first openings at each end, and are formed at intervals,
wherein the second protective film is formed also in the first openings and the second openings and covers a triangle formed by the first openings and the second openings.

7. A method of manufacturing a semiconductor device in which multiple chip regions formed on a wafer are separated by a scribe region,
in formation of the chip region,
the manufacturing method comprising the steps of:
forming an element on a semiconductor substrate;
forming a conductive layer on a periphery of the chip region;
forming interlayer insulating films on the semiconductor substrate, forming a wiring structure in the interlayer insulating films, the wiring structure including wiring layers and vias such that the wiring layers and the vias are electrically connected to the element, simultaneously forming a seal ring in the interlayer insulating films and in an outer region of the chip region, the seal ring including seal wires and seal vias and continuously surrounding the wiring structure and the element, the seal wires and seal vias being electrically connected to the conductive layer;
forming a first passivation film on the interlayer insulating films, the first passivation film having an electrode pad opening above the wiring structure and a cap layer opening above the seal ring;
forming an electrode pad on the electrode pad opening, the electrode pad being connected to the wiring structure;
forming a cap layer on the cap layer opening;
forming a second passivation film on the first passivation film so as to expose the electrode pad and the cap layer;
forming a first protective film on the second passivation film in the chip region and inside the seal ring so as to expose the electrode pad and the cap layer; and
forming a second protective film on the second passivation film in the chip region and outside the seal ring so as to expose the cap layer.

8. The method of manufacturing a semiconductor device according to claim 7, wherein a first groove like a closed loop is further formed between the seal ring and the scribe region and in parallel with an outer periphery of the chip region in the step of forming the first passivation film,
a second groove like a closed loop is further formed on the first groove and in parallel with the outer periphery of the chip region in the step of forming the second passivation film, and
the second protective film is formed also in the first groove and the second groove in the step of forting the second protective film.

9. The method of manufacturing a semiconductor device according to claim 7, wherein a plurality of first openings are further formed between the seal ring and the scribe region, the first openings being formed at intervals in parallel with an outer periphery of the chip region, in the step of forming the first passivation film,
a plurality of second openings are further formed on the respective first openings and in parallel with the outer periphery of the chip region in the step of forming the second passivation film, and
the second protective film is formed also in the first openings and the second openings in the step of forming the second protective film.

10. The method of manufacturing a semiconductor device according to claim 7, further comprising the steps of:
bonding a protective sheet on a major surface of the semiconductor substrate having the second protective film after the step of forming the second protective film, and grinding the semiconductor substrate to a predetermined thickness from a back side of the semiconductor substrate with respect to the major surface; and
dividing the semiconductor substrate into the individual semiconductor devices by dicing the scribe region after the step of grinding the semiconductor substrate.

11. The method of manufacturing a semiconductor device according to claim 7, further comprising the steps of:
forming a third groove from a major surface having the second protective film after the step of forming the second protective film, the third groove having a predetermined depth in the scribe region of the semiconductor substrate; and
bonding a protective sheet on the major surface of the semiconductor substrate after the step of forming the third groove, and dividing the semiconductor substrate into the individual semiconductor devices by grinding the semiconductor substrate to the third groove from a back side of the semiconductor substrate with respect to the major surface.
